(19) United States
(12) Patent Application Publication
(10) Pub. No.: US 2026/0262356 A1
(43) Pub. Date: Sep. 3, 2026

(54) ELECTRONIC APPARATUS AND METHOD OF MANUFACTURING THE SAME, LIGHT EMITTING APPARATUS, AND DISPLAY APPARATUS

(71) Applicant: Sony Group Corporation, Tokyo (JP)

(72) Inventor: Shin AKASAKA, Kanagawa (JP)

(73) Assignee: Sony Group Corporation, Tokyo (JP)

(21) Appl. No.: 18/863,645

(22) PCT Filed: May 15, 2023
(86) PCT No.: PCT/JP2023/018081

§ 371 Date: Nov. 7, 2024

(30) Foreign Application Priority Data
Jun. 3, 2022 (JP) 2022-091164

(51) Int. Cl. H10H 29/853; H10H 29/01

(52) U.S. Cl. CPC H10H 29/853; H10H 29/0362

(57) ABSTRACT

Provided is a compact electronic apparatus having an excellent manufacturability. The electronic apparatus includes an insulating film substrate, a thin film device, and a through via. The insulating film substrate includes a first main surface and a second main surface that is on a side opposite to the first main surface. The thin film device includes a metal layer formed on the first main surface of the insulating film substrate. The through via extends from a first part within the metal layer to pass through the insulating film substrate and reach at least the second main surface.

### TECHNICAL FIELD

The present disclosure relates to an electronic apparatus including a thin film device and a method of manufacturing the same, a light emitting apparatus, and a display apparatus.

### BACKGROUND ART

Up to now, there has been proposed an organic EL display apparatus in which a driving circuit board is provided on a back surface of a substrate including a plurality of organic EL devices formed on a front surface thereof, and the plurality of organic EL devices and the driving circuit board are electrically coupled to each other via a coupling layer passing through the substrate (see, for example, Patent Literature 1).

### CITATION LIST

### Patent Literature

Patent Literature 1: Japanese Unexamined Patent Application Publication No. 2001-92381

### SUMMARY OF THE INVENTION

Incidentally, there is recently a demand for reducing a size and a weight of an electronic apparatus including a plurality of thin film devices.

It is thus desirable to provide a compact electronic apparatus having an excellent manufacturability.

An electronic apparatus according to one embodiment of the present disclosure includes an insulating film substrate, a thin film device, and a through via. The insulating film substrate includes a first main surface and a second main surface that is on a side opposite to the first main surface. The thin film device includes a metal layer formed on the first main surface of the insulating film substrate. The through via extends from a first part within the metal layer to pass through the insulating film substrate and reach the second main surface.

In the electronic apparatus according to one embodiment of the present disclosure, the thin film device is provided on the insulating film substrate, and which makes it advantageous in reduction of a thickness and a weight of an entire configuration. Further, a through hole is easily formed at the time of providing the through via in the insulating film substrate.

### BRIEF DESCRIPTION OF THE DRAWINGS

FIG. 1A is a schematic diagram illustrating an overall configuration example of a display system according to a first embodiment of the present disclosure.

FIG. 1B is a block diagram illustrating a detailed configuration example of components of a portion of the display system illustrated in FIG. 1A.

FIG. 2 is a schematic plan diagram illustrating a planar configuration of a display module illustrated in FIG. 1A.

FIG. 3A is a schematic diagram illustrating an overall configuration example of the display module illustrated in FIG. 1A.

FIG. 3B is a cross-sectional diagram illustrating a cross-sectional configuration example of a display panel illustrated in FIG. 3A.

FIG. 4 is an enlarged cross-sectional diagram illustrating, in an enlarged manner, a portion of a cross section of the display panel illustrated in FIG. 3B.

FIG. 5 is an enlarged cross-sectional diagram illustrating a configuration example of a light source illustrated in FIG. 1A.

FIG. 6A is a first explanatory cross-sectional diagram illustrating a method of manufacturing the display panel illustrated in FIG. 3A.

FIG. 6B is a second explanatory cross-sectional diagram illustrating the method of manufacturing the display panel illustrated in FIG. 3A.

FIG. 6C is a third explanatory cross-sectional diagram illustrating the method of manufacturing the display panel illustrated in FIG. 3A.

FIG. 6D is a fourth explanatory cross-sectional diagram illustrating the method of manufacturing the display panel illustrated in FIG. 3A.

FIG. 6E is a fifth explanatory cross-sectional diagram illustrating the method of manufacturing the display panel illustrated in FIG. 3A.

FIG. 6F is a sixth explanatory cross-sectional diagram illustrating the method of manufacturing the display panel illustrated in FIG. 3A.

FIG. 6G is a seventh explanatory cross-sectional diagram illustrating the method of manufacturing the display panel illustrated in FIG. 3A.

FIG. 6H is an eighth explanatory cross-sectional diagram illustrating the method of manufacturing the display panel illustrated in FIG. 3A.

FIG. 6I is a ninth explanatory cross-sectional diagram illustrating the method of manufacturing the display panel illustrated in FIG. 3A.

FIG. 6J is a tenth explanatory cross-sectional diagram illustrating the method of manufacturing the display panel illustrated in FIG. 3A.

FIG. 6K is an eleventh explanatory cross-sectional diagram illustrating the method of manufacturing the display panel illustrated in FIG. 3A.

FIG. 6L is a twelfth explanatory cross-sectional diagram illustrating the method of manufacturing the display panel illustrated in FIG. 3A.

FIG. 7A is a first explanatory cross-sectional diagram illustrating a method of manufacturing a conductive material layer in the display panel illustrated in FIG. 3A.

FIG. 7B is a second explanatory cross-sectional diagram illustrating the method of manufacturing the conductive material layer in the display panel illustrated in FIG. 3A.

FIG. 7C is a third explanatory cross-sectional diagram illustrating the method of manufacturing the conductive material layer in the display panel illustrated in FIG. 3A.

FIG. 8 is a schematic plan view schematically illustrating an example of a positional relationship between a through via of an insulating film substrate and a wiring layer of a relay substrate in the display panel illustrated in FIG. 3A.

FIG. 9 is a cross-sectional diagram illustrating a configuration example of a light source unit according to a first modification example of the first embodiment.

FIG. 10 is a cross-sectional diagram illustrating a configuration example of a light source unit according to a second modification example of the first embodiment.

FIG. 11 is a cross-sectional diagram illustrating a configuration example of a light source unit according to a third modification example of the first embodiment.

FIG. 12 is a cross-sectional diagram illustrating a configuration example of a light source unit according to a fourth modification example of the first embodiment.

FIG. 13 is a cross-sectional diagram illustrating a configuration example of a light source unit according to a fifth modification example of the first embodiment.

FIG. 14 is a perspective diagram illustrating an external appearance of a display apparatus according to a second embodiment of the present disclosure.

FIG. 15 is a perspective diagram illustrating a main body portion illustrated in FIG. 14 in a disassembled manner.

FIG. 16 is a cross-sectional diagram illustrating an organic EL display apparatus serving as another first modification example of the present disclosure.

FIG. 17A is a first perspective diagram illustrating a state in which a light emitting apparatus serving as another second modification example of the present disclosure is viewed from a first direction.

FIG. 17B is a second perspective diagram illustrating a state in which the light emitting apparatus illustrated in FIG. 17A is viewed from a second direction.

FIG. 18 is a plan diagram illustrating a planar configuration of the light emitting apparatus illustrated in FIG. 17A.

FIG. 19 is a cross-sectional diagram illustrating a cross-sectional configuration of the light emitting apparatus illustrated in FIG. 17A.

FIG. 20 is an enlarged cross-sectional diagram illustrating a configuration example of a wavelength conversion sheet illustrated in FIG. 17A.

FIG. 21A is a first cross-sectional diagram illustrating an example of a method of manufacturing an electronic apparatus according to another third modification example of the present disclosure.

FIG. 21B is a second cross-sectional diagram illustrating the example of the method of manufacturing the electronic apparatus according to the other third modification example of the present disclosure.

FIG. 21C is a third cross-sectional diagram illustrating the example of the method of manufacturing the electronic apparatus according to the other third modification example of the present disclosure.

FIG. 21D is a fourth cross-sectional diagram illustrating the example of the method of manufacturing the electronic apparatus according to the other third modification example of the present disclosure.

FIG. 21E is a first cross-sectional diagram illustrating the example of the method of manufacturing the electronic apparatus according to the other third modification example of the present disclosure.

FIG. 22A is a first cross-sectional diagram illustrating an example of a method of manufacturing an electronic apparatus according to another fourth modification example of the present disclosure.

FIG. 22B is a second cross-sectional diagram illustrating the example of the method of manufacturing the electronic apparatus according to the other fourth modification example of the present disclosure.

FIG. 22C is a third cross-sectional diagram illustrating the example of the method of manufacturing the electronic apparatus according to the other fourth modification example of the present disclosure.

FIG. 22D is a fourth cross-sectional diagram illustrating the example of the method of manufacturing the electronic apparatus according to the other fourth modification example of the present disclosure.

FIG. 22E is a fifth cross-sectional diagram illustrating the example of the method of manufacturing the electronic apparatus according to the other fourth modification example of the present disclosure.

### MODES FOR CARRYING OUT THE INVENTION

Hereinafter, embodiments of the present disclosure are described in detail with reference to the drawings. It is to be noted that description is given in the following order.
1. First Embodiment (a light emitting apparatus)
2. Second Embodiment (a liquid crystal display apparatus)
3. Other Modification Examples

### 1. First Embodiment

### 1.1 Configuration

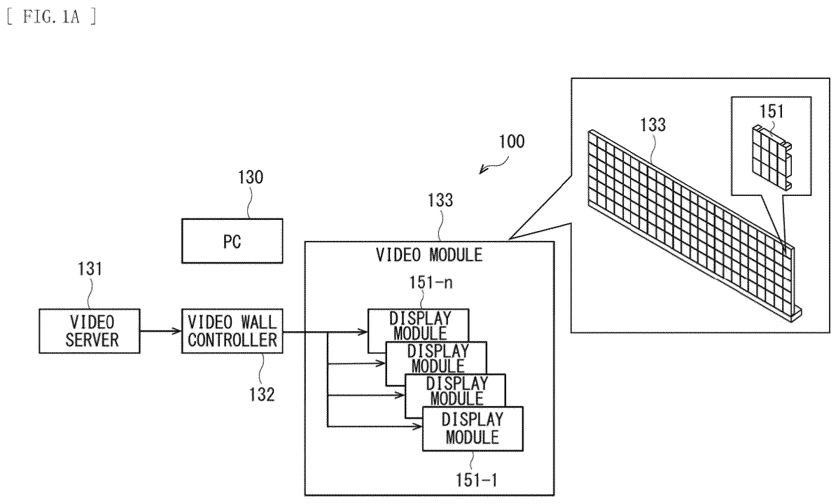

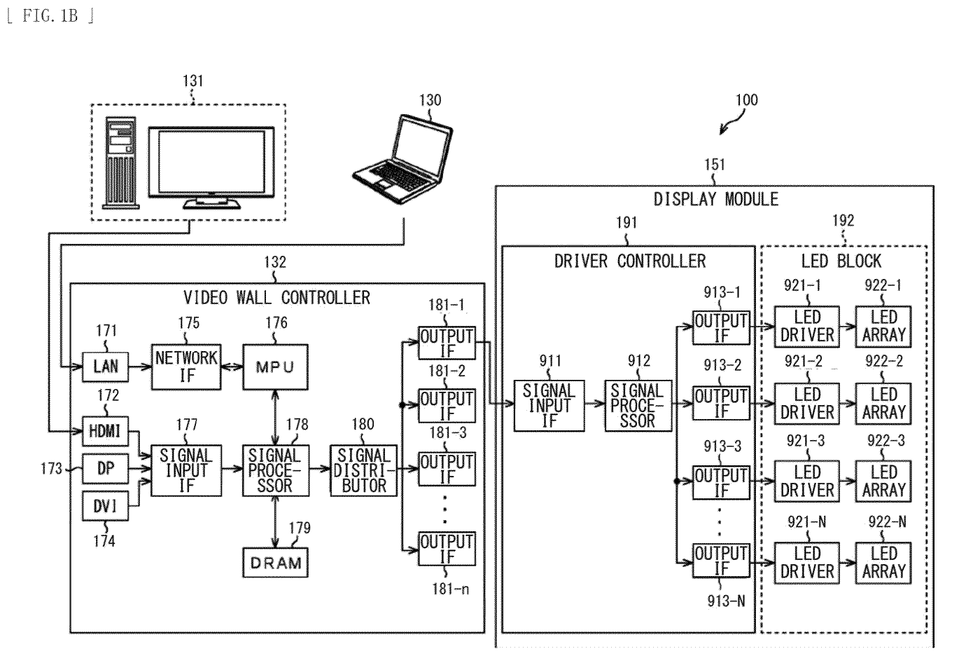

FIG. 1A is a schematic diagram illustrating a configuration example of a display system 100 including a tiling display, as an example of a display system to which the present technique may be applied.

The display system 100 displays, for example, video content on a large-size direct-viewing-type LED display including a plurality of display modules 151 disposed as being tiled. The display system 100 includes a personal computer (PC) 130, a video server 131, a video wall controller 132, and a video wall 133.

The PC 130 is a general all-purpose computer. The PC 130 receives operation input of a user to supply a command corresponding to the operation content to the video wall controller 132.

The video server 131 includes, for example, a server computer. The video server 131 supplies data of a picture signal such as video content to the video wall controller 132.

The video wall controller 132 operates in accordance with a command supplied from the PC 130, and causes data including the picture signal of the video content to be displayed in a distributed manner on display modules 151-1 to 151-n included in the video wall 133. It is to be noted that, in this specification, when the display modules 151-1 to 151-n are not individually discriminated, the display modules 151-1 to 151-n are simply referred to as “display modules 151.”

The video wall 133 includes, as illustrated in the upper right of FIG. 1A, the display modules 151-1 to 151-n in each of which pixels including light emitting diodes (LEDs) are arranged in an array. In the video wall 133, images displayed by the individual display modules 151 are combined as being tiled to display one image as the whole video wall 133. It is to be noted that the video wall controller 132 and the video wall 133 may have an integrated configuration. A display apparatus in which those video wall controller 132 and video wall 133 are integrated may be employed.

FIG. 1B is a block diagram illustrating a detailed configuration example of components of a portion of the display system 100. Specifically, FIG. 1B is a block diagram illustrating a detailed configuration example of the video wall controller 132 and the display module 151.

The video wall controller 132 includes terminals of a LAN terminal 171, an HDMI (registered trademark) terminal 172, a DP terminal 173, and a DVI terminal 174. Further, the video wall controller 32 includes a network IF (Interface) 175, an MPU 176, a signal input IF 177, a signal processor 178, a DRAM 179, a signal distributor 180, and output IFs 181-1 to 181-n.

The LAN (Local Area Network) terminal 171 is, for example, a connection terminal such as a LAN cable. The LAN terminal 171 achieves communication with the PC 130 that supplies a control command or the like corresponding to the operation content of the user to the video wall controller 132, and supplies the input control command or the like to the MPU 176 via the network IF 175.

The LAN terminal 171 may be a configuration to which a wired LAN cable is physically coupled, or may be a configuration that achieves connection by what is called a wireless LAN using wireless communication.

The MPU (Micro Processor Unit) 176 receives input of the control command supplied from the PC 130 via the LAN terminal 171 and the network IF 175, and supplies a control signal corresponding to this control command to the signal processor 178.

The HDMI (registered trademark) (High-Definition Multimedia Interface) terminal 172, the DP (Display Port) terminal 173, and the DVI (Digital Visual Interface) terminal 174 are all input terminals of the data including the picture signal. The HDMI (registered trademark) terminal 172, the DP terminal 173, and the DVI terminal 174 are coupled to the server computer functioning as the video server 131 to supply the data including the picture signal to the signal processor 178 via the signal input IF 177. It is to be noted that the video wall controller 132 may include an input terminal that is on the basis of another standard such as an SDI (Serial Digital Interface) terminal.

FIG. 1B illustrates an example in which the video server 131 and the HDMI (registered trademark) terminal 172 are coupled to each other. The HDMI (registered trademark) terminal 172, the DP terminal 173, and the DVI terminal 174 are all different only in standard, and basically have similar functions. Thus, any of them is selected and coupled as required.

The signal processor 178 adjusts a color temperature, contrast, brightness, or the like of the data including the picture signal supplied via the signal input IF 177, on the basis of the control signal supplied from the MPU 176, and supplies the data subjected to adjustment to the signal distributor 180. At this time, the signal processor 178 uses the coupled DRAM (Dynamic Random Access Memory) 179 as required to load the data including the picture signal and execute signal processing that is on the basis of the control signal, and supplies the signal processing result to the signal distributor 180.

The signal distributor 180 distributes the data including the picture signal supplied from the signal processor 178 and subjected to the signal processing individually to the display modules 151-1 to 151-n via the respective output IFs 181-1 to 181-n.

The display module 151 includes a driver controller 191 and an LED block 192. The driver controller 191 supplies the data including the picture signal for controlling light emission of LEDs included in LED arrays 922-1 to 922-N, to a plurality of LED drivers 921-1 to 921-N included in the LED block 192. The driver controller 191 includes a signal input IF 911, a signal processor 912, and output IFs 913-1 to 913-N.

The signal input IF 911 receives input of the data of the picture signal supplied from the video wall controller 132, and supplies the data to the signal processor 912.

The signal processor 912 performs correction of color and correction of luminance of each display module 151 on the basis of the data of the picture signal supplied from the signal input IF 911 to generate data for setting light emission intensities of the respective LEDs included in the LED arrays 922-1 to 922-N. The generated data is distributed to the LED drivers 921-1 to 921-N of the LED block 192 via the respective output IFs 913-1 to 913-N.

The LED block 192 includes the LED drivers 921-1 to 921-N and the LED arrays 922-1 to 922-N.

In the following, in some cases, the LED drivers 921-1 to 921-N are simply referred to as “LED driver 921,” and the LED arrays 922-1 to 922-N are simply referred to as “LED array 922.”

The LED driver 921 drives the LEDs arranged in the corresponding LED array 922 on the basis of the data for setting the light emission intensities of the LEDs, which is supplied from the driver controller 191, and performs PWM (Pulse Width Modulation) control of the light emission.

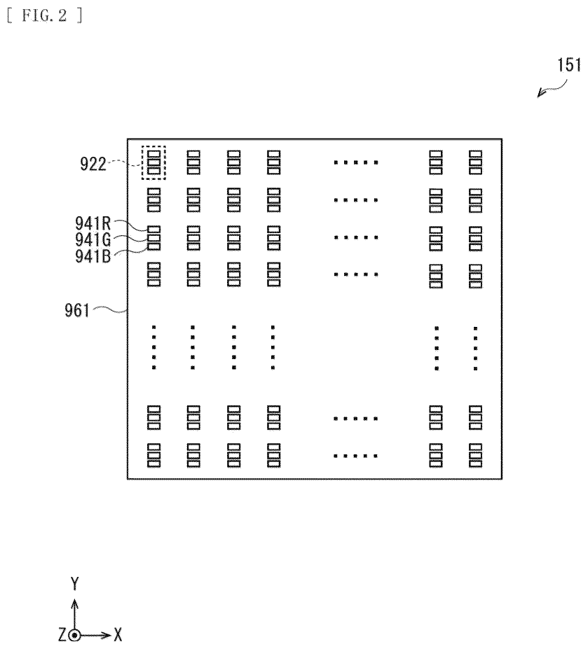

FIG. 2 is a plan diagram illustrating the configuration of the display module 151. As illustrated in FIG. 2, the display module 151 includes the LED arrays 922 disposed in an array on a front surface of a PCB (Printed Circuit Board) substrate 961. Each of the LED arrays 922 configures a pixel in the display module 151.

In the LED array 922, LED chips 941R, 941G, and 941B are mounted. Each of the LED chips 941R, 941G, and 941B is configured by a u-LED which is an ultra-small LED in units of micrometers. The u-LEDs (micro LEDs) configuring the respective LED chips 941R, 941G, and 941B are light emitting devices that respectively emit light beams of a red color, a green color, and a blue color. The LED chips 941R, 941G, and 941B are respectively sub-pixels configuring a unit pixel in the display module 151.

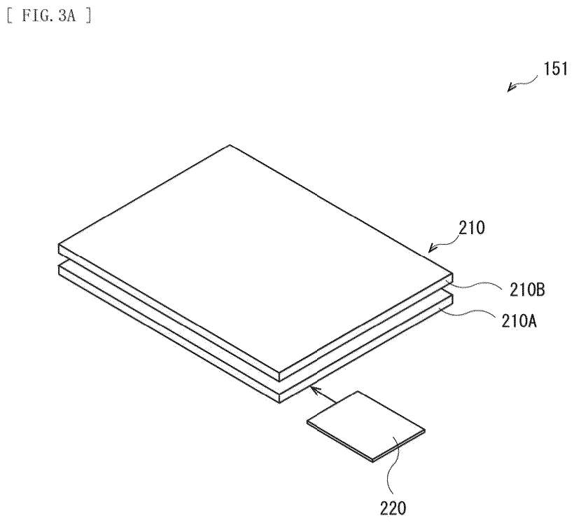

Next, with reference to FIG. 3A and FIG. 3B, the detailed structure of the display module 151 is described. FIG. 3A is a schematic view of the display module 151. The display module 151 includes a display panel 210 and a control circuit 220 that drives and controls the display panel 210. FIG. 3B is a cross-sectional diagram illustrating a portion of the display panel 210.

The display module 151 is what is called an LED display, and uses LEDs as display pixels. The display panel 210 is a specific example corresponding to an “electronic apparatus” of the present disclosure. As illustrated in FIG. 3A, the display panel 210 is obtained by stacking a mounting substrate 210A and a counter substrate 210B on each other. A front surface of the counter substrate 210B (a surface on a side opposite to the mounting substrate 210A) is a picture display surface. The counter substrate 210B has a display region in a middle portion thereof, and has a frame region that is a non-display region around the display region. For example, the counter substrate 210B is disposed at a position opposed to the mounting substrate 210A with a predetermined interval. It is to be noted that the counter substrate 210B may be brought into contact with an upper surface of the mounting substrate 210A. The counter substrate 210B includes, for example, a light transmitting substrate that transmits visible light, and includes, for example, a glass substrate, a transparent resin substrate, or a transparent resin film.

The mounting substrate 210A includes, for example a light source unit 10, a circuit board 20, and a mounting component 56. The circuit board 20 is mechanically joined to a back surface of the counter substrate 210B. The circuit board 20 is also electrically coupled to the counter substrate 210B through a plurality of coupling portions 50.

As illustrated in FIG. 3B, the light source unit 10 includes an insulating film substrate 1 serving as a light source substrate, and a plurality of light sources 2. As illustrated in FIG. 3B, the insulating film substrate 1 includes a front surface 1FS and a back surface 1BS on a side opposite to the front surface 1FS in a thickness direction (Z axis direction). The plurality of light sources 2 is provided on the front surface 1FS of the insulating film substrate 1. The circuit board 20 is provided on the back surface 1BS side of the insulating film substrate 1.

The counter substrate 210B includes a thin film device 4 including a driving device 41. For example, the driving device 41 is provided on the insulating film substrate 1 of the light source unit 10. The counter substrate 210B may further include, as illustrated in FIG. 3B, for example, a resin layer 61. Further, a transparent sealing layer 60 may be provided between the light source unit 10 and the resin layer 61. For example, the sealing layer 60 is configured by an organic film such as a silicone resin, an acrylic resin, or an epoxy resin, or an inorganic film such as a Si-based compound layer (SiNx, SiOx, SiONx, or SiOCx) or a TEOS film. The sealing layer 60 has a single layer structure of the above-described organic film or inorganic film, or a stacking structure of those films. The sealing layer 60 may be a composite film of the above-described organic film and inorganic film. It is possible to form the inorganic film by, for example, an ALD (Atomic Layer Deposition) method or a CVD (Chemical Vapor Deposition) method.

### Light Source Unit 10

The light source unit 10 includes, as illustrated in FIG. 3B, the insulating film substrate 1, the plurality of light sources 2, the thin film device 4 and an insulating layer 4Z, and a resin layer 5. The insulating film substrate 1 is, for example, a film-like member that includes, for example, an organic material such as a resin, and has electrical insulation performance. The insulating film substrate 1 is preferred to have flexibility. As the insulating film substrate 1, it is possible to use a resin film including, for example, PI (polyimide), PET (polyethylene terephthalate), PC (polycarbonate), PEN (polyethylene naphthalate), PEI (polyether imide), COP (cyclo-olefin polymer), LCP (liquid crystal polymer), or a fluororesin. As another example, as the insulating film substrate, one obtained by forming an insulating resin layer of polyimide, an epoxy-based material, or the like on a surface of a metal-based substrate of aluminum (Al) or the like may be used. As further another example, as the insulating film substrate 1, a film base material including a glass-containing resin such as a glass epoxy resin typified by FR4 or a glass composite resin typified by CEM3 may be used. The insulating film substrate 1 includes the front surface 1FS serving as a first main surface and the back surface 1BS serving as a second main surface. The plurality of light sources 2 and the plurality of thin film devices 4 provided on the insulating layer 4Z are mounted on the front surface 1FS of the insulating film substrate 1. The thin film device 4 includes at least one of a wiring layer or a thin film transistor. In this embodiment, the thin film device 4 includes the driving device 41 that is a thin film transistor.

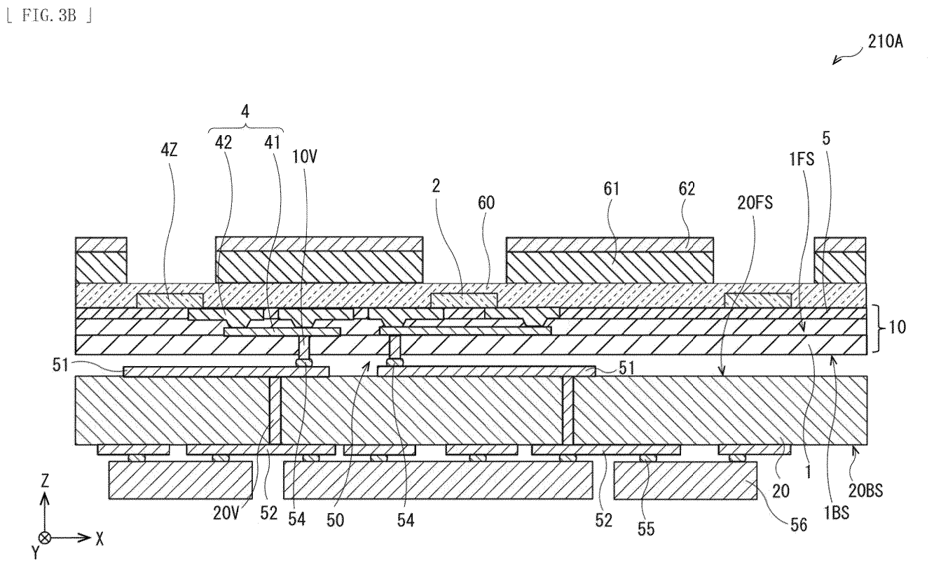

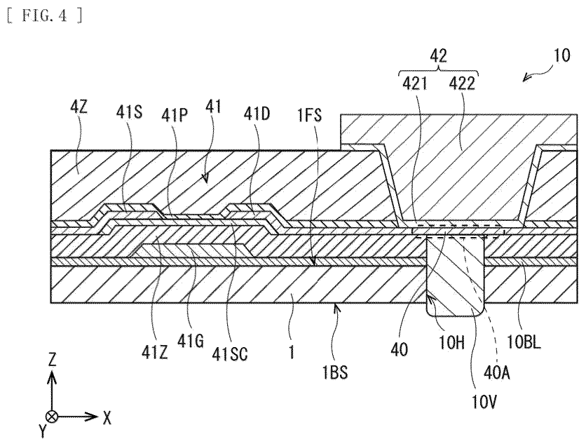

FIG. 4 is an enlarged cross-sectional diagram illustrating, in a further enlarged manner, a portion of the light source unit 10 illustrated in FIG. 3B. As illustrated in FIG. 4, the thin film device 4 further includes a metal layer 40 provided on the front surface 1FS of the insulating film substrate 1, and a wiring layer 42 selectively stacked in an overlapping portion 40A within the metal layer 40. The wiring layer 42 is, for example, an additional metal layer that may be configured by the same material as the metal layer 40. It is to be noted that the thickness of the wiring layer 42 is allowed to be larger than the thickness of the metal layer 40. Further, the circuit board 20 (see FIG. 3B) is disposed to be opposed on the back surface 1BS of the insulating film substrate 1. As illustrated in FIG. 3B, a wiring layer 51 is formed on a front surface 20FS of the circuit board 20 opposed to the back surface 1BS of the insulating film substrate 1, and a wiring layer 52 is formed on a back surface 20BS thereof on a side opposite to the front surface 20FS. The wiring layer 51 and the wiring layer 52 are coupled to each other through a through via 20V passing through the circuit board 20 in the Z axis direction.

As described above, the light source unit 10 is coupled to the circuit board 20 via the coupling portion 50. Specifically, the driving device 41 provided on the insulating film substrate 1 is coupled to the wiring layer 51 provided on the front surface 20FS of the circuit board 20 via the metal layer 40, a through via 10V passing through the insulating film substrate 1, and a conductive material layer 54 provided at a distal end of the through via 10V. The through via 10V extends in the Z axis direction from the overlapping portion 40A of the metal layer 40 overlapping the wiring layer 42 to pass through the insulating film substrate 1 to be exposed to the back surface 1BS. It is to be noted that it is possible to form the through via 10V by, for example, selectively digging a predetermined region of the back surface 1BS of the insulating film substrate 1 by laser processing to form a via hole, and then filling this via hole with a conductive material. At this time, the metal layer 40 and the wiring layer 42 formed on the front surface 1FS serve as an etching stopper.

Moreover, the mounting component 56 is provided on the back surface 20BS of the circuit board 20. The mounting component 56 is coupled to the wiring layer 52 provided on the back surface 20BS, via a conductive material layer 55.

### Light Source 2 and Thin Film Device 4

The plurality of light sources 2 is provided on the front surface 1FS of the insulating film substrate 1. On the front surface 1FS of the insulating film substrate 1, a plurality of wiring layers 42 having a predetermined pattern shape is formed to allow independent light emission control for each light source 2 or every two or more light sources 2. The plurality of wiring layers 42 allows display control of the plurality of light sources 2. The driving device 41 is a driver IC that drives each light source 2, that is, that turns on and off each light source 2.

The driving device 41 is, for example, a bottom-gate thin film transistor. The driving device 41 includes, for example, a gate electrode 41G, a gate insulating film 41Z, a semiconductor layer 41SC, a source electrode 41S, a drain electrode 41D, and a protective film 41P. In this embodiment, the metal layer 40 is provided integrally with the drain electrode 41D. It is to be noted that the metal layer 40 may be formed in the same layer as the gate electrode 41G.

The gate electrode 41G controls a carrier density of the semiconductor layer 41SC by a gate voltage applied to the driving device 41. The gate electrode 41G is configured by, for example, one or more types among Mo (molybdenum), Al (aluminum), and an aluminum alloy. The gate electrode 41G may be a single layer film or a multilayer film.

The gate insulating film 41Z is configured by one or more types among SiO₂, Si₃N₄, SiON (silicon oxynitride), and an aluminum oxide (Al₂O₃). The gate insulating film 41Z may be a single layer film or a multilayer film.

The semiconductor layer 41SC includes, as a main component, for example, an oxide of at least one type among Si (silicon), In (indium), Ga (gallium), Zn (zinc), Sn (tin), Al (aluminum), and Ti (titanium). Examples of a material including silicon include amorphous silicon and low-temperature polysilicon. The semiconductor layer 41SC forms a channel between the source electrode 41S and the drain electrode 41D through application of the gate voltage.

The source electrode 41S and the drain electrode 41D are configured by, for example, one or more types among Mo (molybdenum), Al (aluminum), Cu (copper), Ti (titanium), ITO, and TiO. The source electrode 41S and the drain electrode 41D may each be a single layer film or a multilayer film.

The insulating layer 4Z is configured by an organic material such as polyimide.

As illustrated in FIG. 4, the light source unit 10 may further include a buffer layer 10BL. The buffer layer 10BL is provided between the front surface 1FS of the insulating film substrate 1 and the thin film device 4. The buffer layer 10BL may include an organic material or an inorganic material. As the organic material configuring the buffer layer 10BL, it is possible to use polyimide, acrylic, epoxy, or an insulating resin such as silicone. Further, as the inorganic material configuring the buffer layer 10BL, for example, inorganic insulating materials such as SiNx (silicon nitride), SiOx (silicon oxide), SiON (silicon oxynitride), Al₂O₃ (aluminum oxide), or TEOS (tetraethyl orthosilicate) are given. With the buffer layer 10BL being provided, it is possible to prevent water vapors passing through the insulating film substrate 1 from entering the thin film device 4. Further, when the insulating film substrate 1 may cause deformation such as deflection or swell due to moisture absorption, with the buffer layer 10BL being provided, it is possible to prevent the insulating film substrate 1 from being deformed by the moisture absorption. Moreover, the insulating film substrate 1 often has remarkable scratches and unevenness on the front surface 1FS as compared with, for example, a glass substrate. Thus, it is possible to form a smooth front surface by providing the buffer layer 10BL to uniformly cover the front surface 1FS. With the driving device 41 being provided on the smooth buffer layer 10BL, improvement of the stability of the performance of the driving device 41 is expectable.

The wiring layer 42 is formed by patterning processing by using a photolithography method after, for example, bonding a copper foil to the insulating film substrate 1. As another example, the wiring layer 42 may be formed by patterning processing by using a photolithography method after forming a metal film on the insulating film substrate 1 by using plating or a vacuum film formation technique. Moreover, the wiring layer 42 may be formed by a printing method such as screen printing or an inkjet method. Examples of a constituent material of the wiring layer 42 include copper (Cu), aluminum (Al), silver (Ag), and an alloy of those. It is to be noted that the wiring layer 42 is preferred to have a thickness of, for example, 1 μm or more. One reason for this is that the wiring layer 42 may serve as an etching stopper at the time of etching processing such as laser processing for forming a via hole to be filled with the through via 10V. Thus, in order to efficiently form a wiring layer 42 having a larger thickness, the wiring layer 42 is preferred to have a stacking structure of a first layer 421 that is a metal thin film and a second layer 422 that is a metal layer having a thickness larger than that of the first layer 421. For example, the first layer 421 may be a plating base layer, and the second layer 422 may be a plating layer formed by plating treatment using the first layer 421 as a plating base layer.

### Resin Layer 5

The resin layer 5 is, for example, a transparent insulating film (acrylic-based or epoxy-based), a black insulating film (a material obtained by mixing black particles such as black carbon to an acrylic-based or epoxy-based material), or a stacking film obtained by stacking a black insulating film on an inorganic insulating film. The resin layer 5 is preferred to transmit light from the light source 2 as much as possible, or not to reflect the light from the light source 2 as much as possible.

### Details of Light Source 2

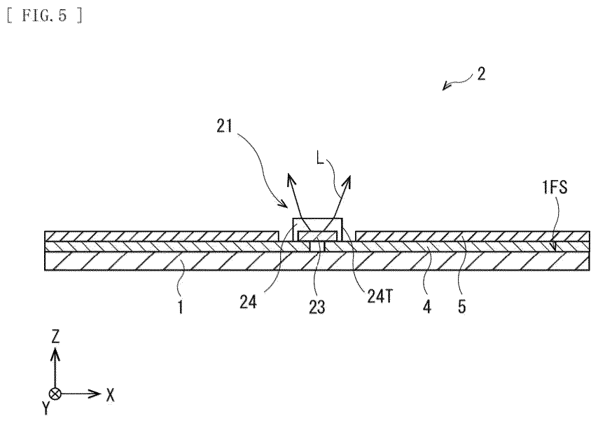

FIG. 5 is an enlarged cross-sectional diagram illustrating a configuration example of the light source 2 illustrated in FIG. 1. As illustrated in FIG. 5, the light source 2 includes a light emitting device 21. The light emitting device 21 includes, for example, a semiconductor layer 23 including a luminous body, and the semiconductor layer 23 and a transparent layer 24.

The transparent layer 24 is configured by, for example, sapphire or silicon carbide (SiC). The semiconductor layer 23 is formed by stacking, for example, from the transparent layer 24 side, an n-type semiconductor layer, an active layer, and a p-type semiconductor layer in the stated order. The n-type semiconductor layer is configured by, for example, an n-type nitride semiconductor (for example, n-type GaN). The active layer is configured by, for example, a nitride semiconductor (for example, n-type GaN) having a quantum well structure. The p-type semiconductor layer is configured by, for example, a p-type nitride semiconductor (for example, p-type GaN). The semiconductor layer 23 is configured by, for example, a blue LED (Light Emitting Diode; light emitting diode) that emits blue light (for example, a wavelength of 440 nm to 460 nm).

As illustrated in FIG. 5, in the light emitting device 21, light L emitted from the active layer of the semiconductor layer 23 passes through the transparent layer 24 to travel upward.

It is to be noted that the light source 2 may further include, for example, a sealing lens having a dome shape (hemispherical shape) to cover the light emitting device 21.

Further, the resin layer 61 and a resin layer 62 may be selectively provided on the sealing layer 60. The resin layer 61 and the resin layer 62 have openings provided in regions overlapping the light source 2 in the Z axis direction, and thus do not hinder transmission of the light L from the light source 2. The resin layer 61 includes, for example, a black resin having high light shielding performance. The resin layer 62 is a protective layer that protects the resin layer 61, and it is possible to use an epoxy resin, an acrylic resin, or a urethane resin that has a high hardness and a low reflectance. The resin layer 61 and the resin layer 62 are not required to be provided.

### Circuit Board 20

The circuit board 20 is a member that is electrically and mechanically coupled to the light source unit 10 and performs relay between the light source unit 10 and a power supply circuit, a driving circuit, or other circuits. The circuit board 20 may be configured by, for example, a film member having flexibility similarly to the insulating film substrate 1. As the constituent material of the circuit board 20, it is possible to use a constituent material similar to that of the insulating film substrate 1. That is, as the circuit board 20, it is possible to use a resin film including, for example, PI (polyimide), PET (polyethylene terephthalate), PC (polycarbonate), PEN (polyethylene naphthalate), PEI (polyetherimide), LCP (liquid crystal polymer), or a fluororesin. As another example, as the circuit board 20, one obtained by forming an insulating resin layer of polyimide, an epoxy-based material, or the like on a surface of a metal-based substrate of aluminum (Al) or the like may be used. As further another example, as the circuit board 20, a film base material including a glass-containing resin such as a glass epoxy resin typified by FR4 or a glass composite resin typified by CEM3 may be used. A plurality of wiring layers 52 is formed on the front surface 20FS of the circuit board 20, that is, a surface opposed to the insulating film substrate 1. Further, a plurality of wirings 53 is formed on the back surface 20BS of the circuit board 20, that is, a surface on a side opposite to the insulating film substrate 1. As described above, the wiring layer 51 and the wiring layer 52 are electrically continuous with each other via, for example, the through via 20V.

Further, the circuit board 20 is joined to the light source unit 10 via the conductive material layer 54. Specifically, for example, the through via 10V and the wiring layer 51 provided on the front surface 20FS of the circuit board 20 are joined to each other to sandwich the conductive material layer 54. It is to be noted that the light source unit 10 and the circuit board 20 are preferred to be joined to each other via the conductive material layer 54 at a plurality of portions. One reason for this is that, with the light source unit 10 and the circuit board 20 being coupled to each other at multiple points, the light source unit 10 is held more stably with respect to the circuit board 20. Further, it is possible to secure a plurality of channels such as signal transmission paths or power supply paths between the light source unit 10 and the circuit board 20, which makes it possible to provide a larger number of functions. For the same reason, the mounting component 56 is also preferred to be joined to the circuit board 20 via the conductive material layer 55 at a plurality of portions. Further, as constituent materials of the conductive material layers 54 and 55, for example, conductive paste and solder, or an anisotropic conductive adhesive (ACA) is suitably used.

### 1.2 Manufacturing Method

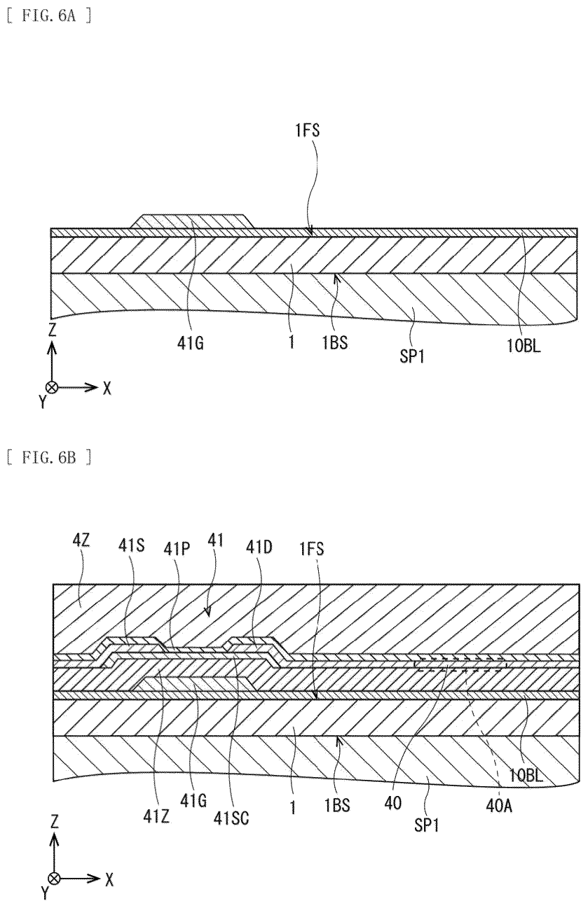

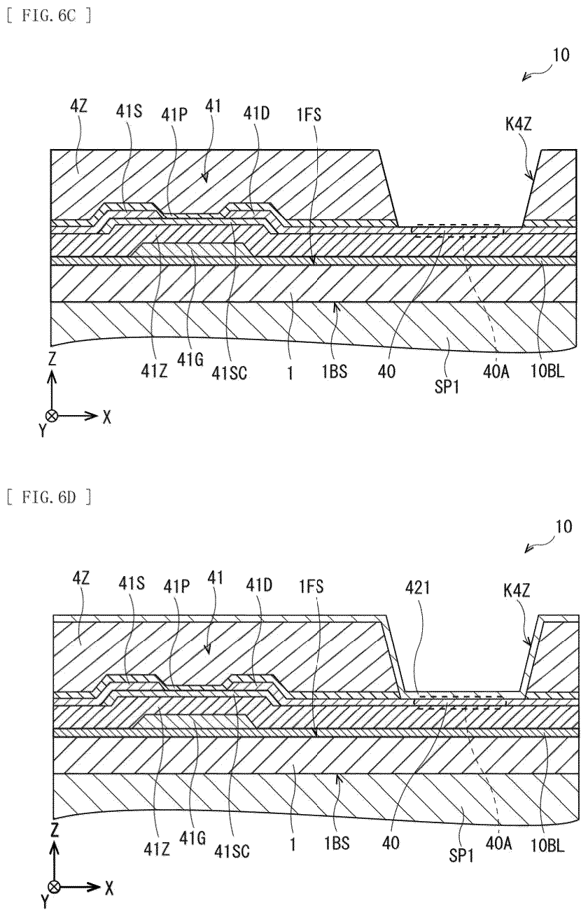

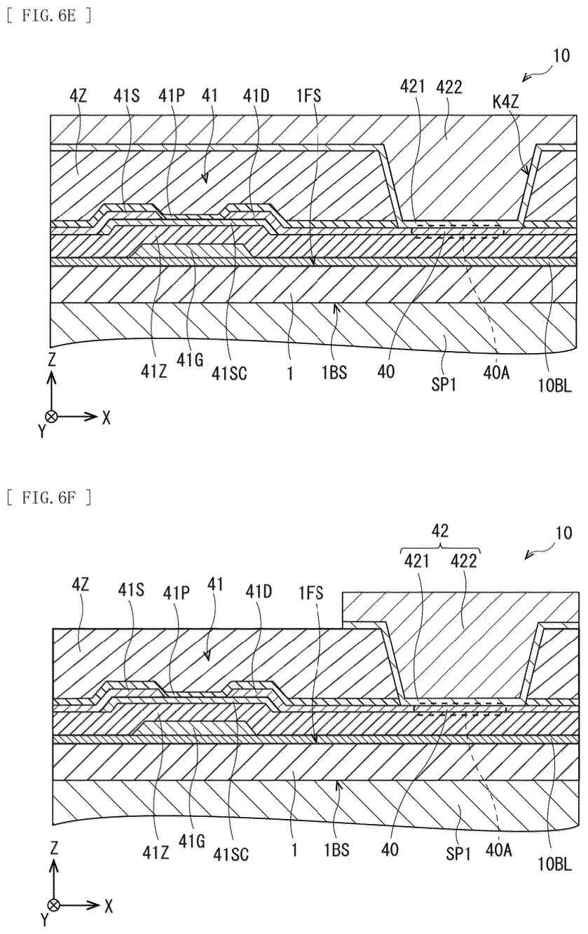

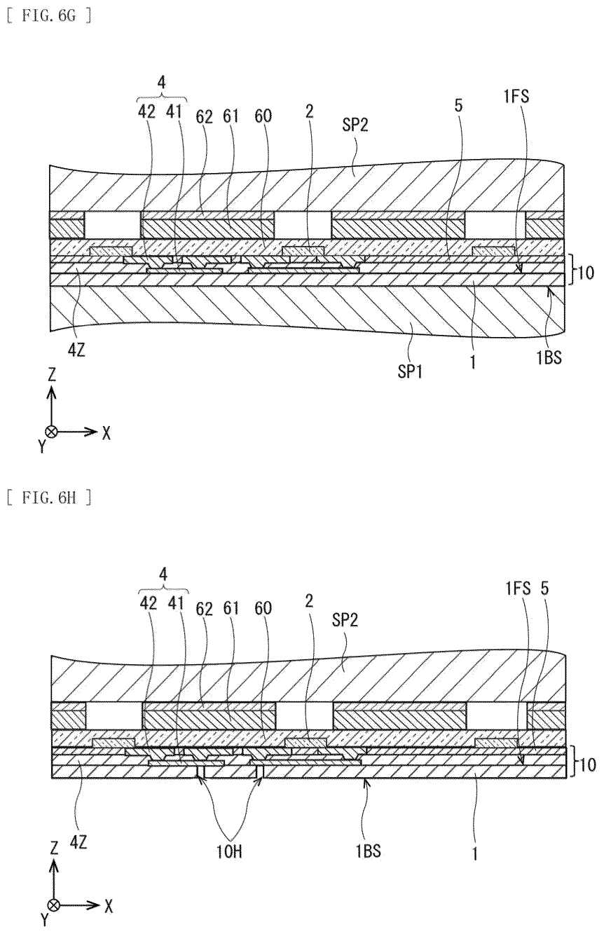

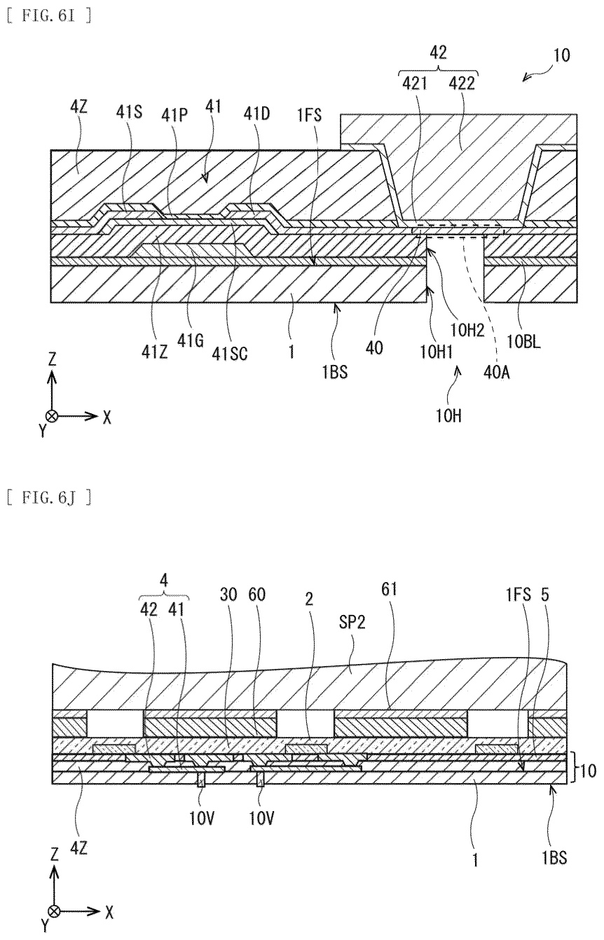

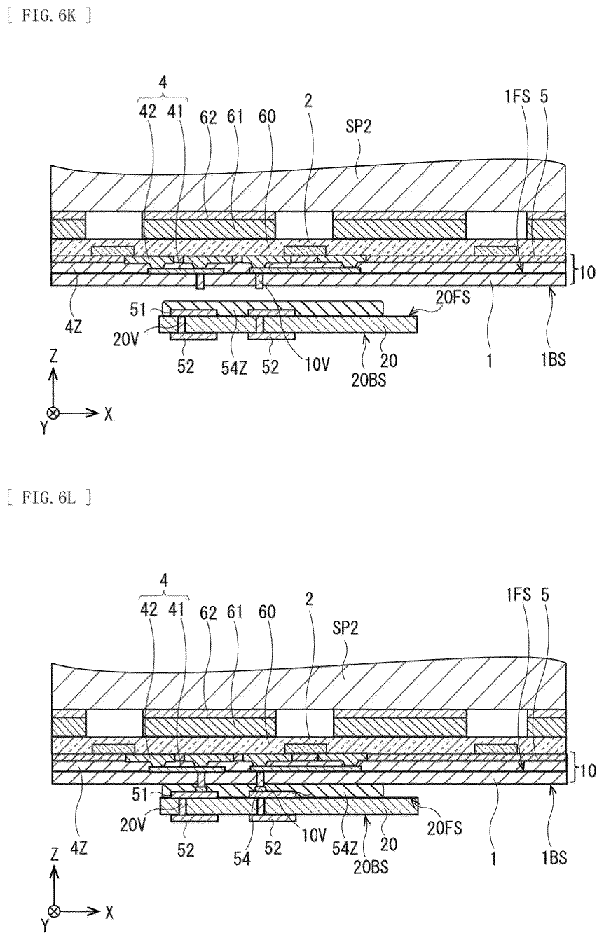

Next, with reference to FIG. 6A to FIG. 6L, description is given of a method of manufacturing the mounting substrate 210A of the display panel 210.

First, as illustrated in FIG. 6A, a support SP1 is bonded to the back surface 1BS of the insulating film substrate 1 with an adhesive or the like. The support SP1 is preferred to be configured by, for example, a high rigidity material such as glass, quartz, silicon, or ceramic. Then, the buffer layer 10BL is formed to uniformly cover the front surface 1FS of the insulating film substrate 1. The front surface 1FS may be cleaned before forming the buffer layer 10BL. Examples of a cleaning method include water cleaning, organic cleaning, ultrasonic cleaning, UV (ultraviolet) cleaning, and ozone cleaning. Predetermined pretreatment may be further performed before forming the buffer layer 10BL. Specifically, it is possible to perform UV treatment, plasma treatment, coating treatment of silane coupling agents, or the like to improve the adhesion between the front surface 1FS and the buffer layer 10BL. As a method of forming the buffer layer 10BL, in a case where the buffer layer 10BL is formed of a resin material, it is possible to use, for example, slit coating, screen printing, gravure printing, spin coating, or spray coating. In a case where the buffer layer 10BL is formed of an inorganic material, it is possible to use, in addition to the various methods described above, a CVD (chemical vapor deposition) method, a PVD (physical vapor deposition) method, an ALD (atomic layer deposition) method, a sputtering method, or other methods. Moreover, the buffer layer 10BL may be subjected to heat treatment as required. After the buffer layer 10BL is formed, the gate electrode 41G is selectively formed at a predetermined position on the buffer layer 10BL.

Subsequently, as illustrated in FIG. 6B, the gate insulating film 41Z, the semiconductor layer 41SC, the source electrode 41S and the drain electrode 41D, the protective film 41P, and the insulating layer 4Z are sequentially formed. The metal layer 40 integrated with the drain electrode 41D is formed at the same time as the formation of the source electrode 41S and the drain electrode 41D.

Subsequently, as illustrated in FIG. 6C, partial regions of the insulating layer 4Z and the protective film 41P are selectively removed to form an opening K4Z passing through the insulating layer 4Z and the protective film 41P. This exposes the overlapping portion 40A of the metal layer 40.

Subsequently, as illustrated in FIG. 6D, the first layer 421 is formed by, for example, a sputtering method to entirely cover the exposed portions of the insulating layer 4Z and the metal layer 40. After that, as illustrated in FIG. 6E, the second layer 422 is stacked on the first layer 421 by a plating method using the first layer 421 as a plating base layer to form a stacking film. At this time, the second layer 422 is formed to fill the opening K4Z. Further, as illustrated in FIG. 6F, the wiring layer 42 is obtained by patterning the stacking film of the first layer 421 and the second layer 422 by, for example, a photolithography method. It is to be noted that the thickness of the wiring layer 42 is desirably, for example, 2 μm or more.

Subsequently, as illustrated in FIG. 6G, the resin layer 5, the light source 2, the sealing layer 60, the resin layer 61, and the resin layer 62 are sequentially formed. Moreover, a support SP2 is bonded to the surface of the resin layer 62 with an adhesive or the like. The support SP2 is preferred to include, for example, a high rigidity material such as glass, quartz, silicon, or ceramic.

Subsequently, as illustrated in FIG. 6H, after the support SP1 is peeled off from the back surface 1BS of the insulating film substrate 1, a predetermined region of the back surface 1BS is selectively removed to form a through hole 10H. It is possible to form the through hole 10H by laser irradiation.

In more detail, as illustrated in FIG. 6I, the through hole 10H is formed at a position overlapping the overlapping portion 40A in the Z axis direction within the metal layer 40 integrated with the drain electrode 41D. FIG. 6I is an enlarged cross-sectional diagram illustrating, in an enlarged manner, a portion of a cross-sectional configuration of the light source unit 10 in the middle of manufacture in the same step as FIG. 6H. The through hole 10H is one in which a first through hole 10H1 and a second through hole 10H2 are formed to communicate with each other. The first through hole 10H1 passes through the insulating film substrate 1, and the second through hole 10H2 passes through the buffer layer 10BL and the gate insulating film 41Z. It is to be noted that, in order to form the through hole 10H, it is possible to form the first through hole 10H1 under a first laser irradiation condition, and then form the second through hole 10H1 under a second laser irradiation condition different from the first laser irradiation condition. As another example, the through hole 10H may be obtained by forming the first through hole 10H1 and subsequently forming the second through hole 10H2 under the same laser irradiation condition. For example, in a case where both the insulating film substrate 1 and the buffer layer 10BL include organic materials, it is possible to successively form the first through hole 10H1 and the second through hole 10H2 using nanosecond laser under the same laser irradiation condition. However, in a case where the insulating film substrate 1 includes an organic material and the buffer layer 10BL includes an inorganic material, it is difficult to successively form the first through hole 10H1 and the second through hole 10H2 using nanosecond laser. In this case, for example, the insulating film substrate 1 and the buffer layer 10BL are sequentially irradiated with picosecond laser (short pulse laser) to cause multiphoton absorption in both of the insulating film substrate 1 and the buffer layer 10BL. This makes it possible to successively form the first through hole 10H1 and the second through hole 10H2. In a case where the through hole 10H is formed by laser irradiation, the wiring layer 42 functions as an etching stopper.

After the through hole 10H is formed, as illustrated in FIG. 6J, the through hole 10H is filled with a conductive material to form the through via 10V.

After the through via 10V is formed, as illustrated in FIG. 6K, the circuit board 20 having the mounting component 56 provided on the back surface 20BS is prepared. An adhesive material 54Z in which a conductive filler is included in an insulating resin is applied in advance to the front surface 20FS of the circuit board 20 to cover the wiring layer 51.

Subsequently, as illustrated in FIG. 6L, the circuit board 20 is pressed against the insulating film substrate 1 to allow the anisotropic conductive adhesive 54Z to be sandwiched between a distal end portion of the through via 10V and the wiring layer 51. This causes the anisotropic conductive adhesive 54Z pressed between the distal end portion of the through via 10V and the wiring layer 51 to become the conductive material layer 54, and the circuit board 20 is joined to the insulating film substrate 1.

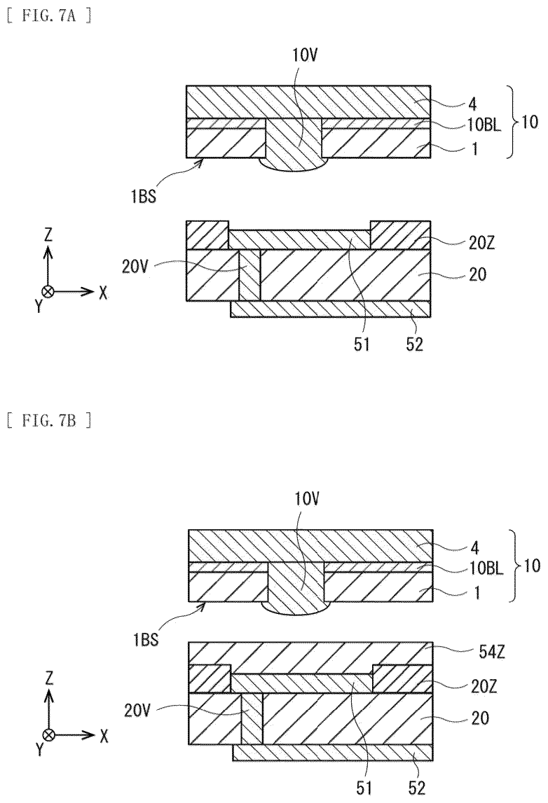

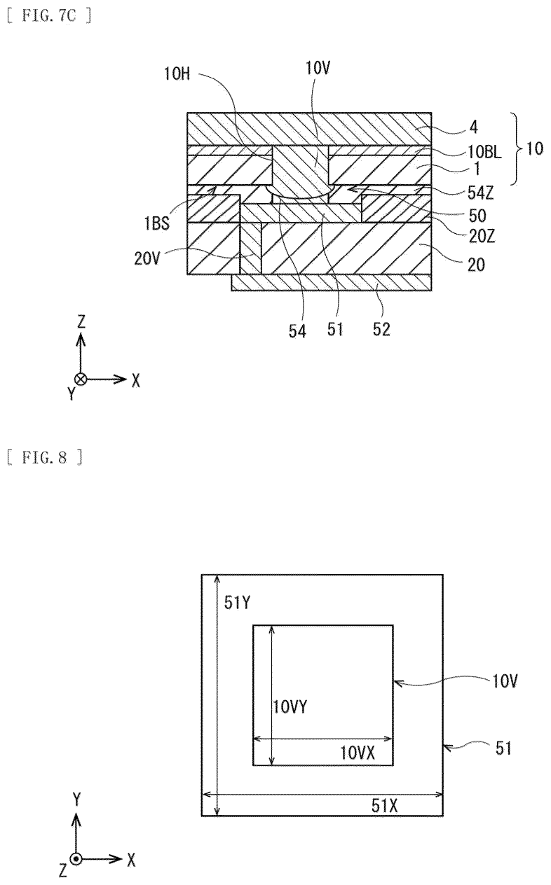

FIG. 7A to FIG. 7C are cross-sectional views illustrating a process of forming the conductive material layer 54 in the mounting substrate 210A. First, as illustrated in FIG. 7A, the distal end portion of the through via 10V of the light source unit 10 and the wiring layer 51 of the circuit board 20 are opposed to each other. It is to be noted that, around the wiring layer 51, an insulating layer 20Z having a thickness larger than the thickness of the wiring layer 51 is provided. Next, as illustrated in FIG. 7B, the anisotropic conductive adhesive 54Z is applied onto the wiring layer 51 and the insulating layer 20Z. It is to be noted that the anisotropic conductive adhesive 54Z may be formed to cover the distal end portion of the through via 10V and the back surface 1BS of the insulating film substrate 1. Finally, pressing is performed to sandwich the anisotropic conductive adhesive 54Z between the distal end portion of the through via 10V and the wiring layer 51. Thus, as illustrated in FIG. 7C, the conductive material layer 54 is formed. As a result, the light source unit 10 and the circuit board 20 are joined to each other. As described above, the conductive material layer 54 is formed, and the coupling portion 50 is completed.

Through the above-described steps, the mounting substrate 210A is completed. After that, the counter substrate 210B is stacked on the mounting substrate 210A, and thus the display panel 210 is completed.

It is to be noted that, as illustrated in FIG. 8, in the mounting substrate 210A, it is desirable that a dimension 10VX in the X axis direction and a dimension 10VY in the Y axis direction of the through via 10V be smaller than a dimension 51X in the X axis direction and a dimension 51Y in the Y axis direction of the exposed portion of the opposed wiring layer 51. FIG. 8 is a schematic plan view schematically illustrating an example of a positional relationship between the through via 10V and the exposed portion of the wiring layer 51 in an XY plane. In the mounting substrate 210A, it is desirable that, for example, the dimension 51X be 1.5 times or more and 3 times or less the dimension 10VX and the dimension 51Y be 1.5 times or more and 3 times or less the dimension 10VY. When the dimension in the XY plane of the through via 10V is made smaller than the dimension in the XY plane of the exposed portion of the wiring layer 51 as described above, it is possible to ensure a margin at the time of positioning the light source unit 10 and the circuit board 20 in the XY plane. It is to be noted that FIG. 8 exemplifies a case where the dimension 10VX and the dimension 10VY are substantially equal to each other and the dimension 51X and the dimension 51 Y are substantially equal to each other, but the present disclosure is not limited to this case. That is, both of the planar shape of the through via 10V and the planar shape of the exposed portion of the wiring layer 51 are not limited to a case of substantially square shapes, and may be substantially rectangular shapes. As another example, the planar shapes thereof may be rectangular shapes with rounded corners, or may be substantially circular shapes or substantially elliptical shapes.

### 1.2 Actions

The display panel 210 of this embodiment uses the insulating film substrate 1, and hence the display panel 210 has advantages of being reduced in thickness and weight as compared with the case of using the glass substrate. Further, the through via 10V is used to ensure an electrical coupling path from the back surface 1BS of the insulating film substrate 1 to reach the thin film device 4. This makes it unnecessary to provide wiring around the light emission region of the front surface 1FS of the insulating film substrate 1. Thus, for example, when a plurality of display modules 151 each including the display panel 210 is arrayed, it is possible to form a larger seamless display region.

Further, in the display panel 210, it is possible to form, in the insulating film substrate 1, the through hole 10H to be filled with the through via 10V after by etching processing such as laser processing using the metal layer 40 as an etching stopper. This is suitable for easily forming even the through via 10V having fine dimensions while ensuring a high positional accuracy and a high dimensional accuracy of the through via 10V.

Further, in the display panel 210, the metal layer 40 is formed integrally with the drain electrode 41D, and hence the manufacturing process is simplified as compared with the case where the metal layer 40 is individually formed. It is to be noted that, in this embodiment, the metal layer 40 may be formed integrally with the source electrode 41S.

Further, the display panel 210 further includes the wiring layer 42 selectively stacked on the overlapping portion 40A within the metal layer 40. That is, as viewed from the overlapping portion 40A of the metal layer 40, the wiring layer 42 is provided on the side opposite to the insulating film substrate 1. This allows the wiring layer 42 to be used as an etching stopper when the through hole 10H is formed by etching processing. Thus, provision of the wiring layer 42 makes it unnecessary to form the metal layer 40 into a thickness suitable as an etching stopper, and hence it is possible to further reduce the thickness of the metal layer 40 or the thickness of the thickness of each of the drain electrode 41D and the source electrode 41S formed collectively with the metal layer 40.

Further, the display panel 210 further includes the buffer layer 10BL provided between the front surface 1FS of the insulating film substrate 1 and the thin film device 4. Thus, even when the front surface 1FS has scratches or unevenness, it is possible to form a smooth surface by providing the buffer layer 10BL. With the driving device 41 being provided on the buffer layer 10BL having a smooth surface, improvement of the stability of the performance of the driving device 41 is expectable. In particular, in a case where the buffer layer 10BL is configured by an inorganic material, a smother surface may be obtained as compared with the case where the buffer layer 10BL is configured by an organic material.

Further, in the process of manufacturing the display panel 210, multiphoton absorption may be caused in both of the insulating film substrate 1 and the buffer layer 10BL through irradiation of short pulse laser to successively form the first through hole 10H1 and the second through hole 10H2. In such a case, it is possible to reduce the lead time of the manufacturing process.

Further, in the display panel 210, the light source unit 10 and the circuit board 20 are joined to each other via the conductive material layer 54. Accordingly, for example, as compared with a case of achieving joining via a connector, it is possible to simplify, downsize, thin, and reduce the weight of each coupling portion between the light source unit 10 and the circuit board 20. Thus, it is possible to downsize the display panel 210 as compared with the case of using the connector, and it is possible to increase the number of light sources 2 per unit region. That is, it is possible to achieve high integration of the plurality of light sources 2. Further, as compared with the case of using the connector, the manufacturability is also improved. In particular, in the display panel 210, the light source unit 10 and the circuit board 20 are each joined by the conductive material layer 54 at a plurality of portions. When the light source unit 10 and the circuit board 20 are each coupled at multiple points as described above, the light source unit 10 is more stably held with respect to the circuit board 20. Further, it is possible to secure a plurality of channels such as signal transmission paths or power supply paths between each light source unit 10 and the circuit board 20, and hence it is possible for the display panel 210 to have a larger number of functions.

Further, in the display panel 210, the display panel 210 has flexibility, or both of the insulating film substrate 1 and the circuit board 20 have flexibility. This makes it possible to achieve, for example, a display system 100 including a curved screen.

### 1.3 Effects

As described above, according to the display panel 210 of this embodiment, the thin film device 4 is provided on the insulating film substrate 1. This makes it possible to reduce the thickness and the weight of the entire configuration. Further, the formation of the through hole 10H at the time of providing the through via 10V in the insulating film substrate 1 is facilitated. Thus, it is possible to achieve a compact display panel 210 having an excellent manufacturability. Further, it is also possible to exert excellent light emission performance while the plurality of light sources is disposed at a higher density.

### 1.4 Modification Examples of First Embodiment

### First Modification Example

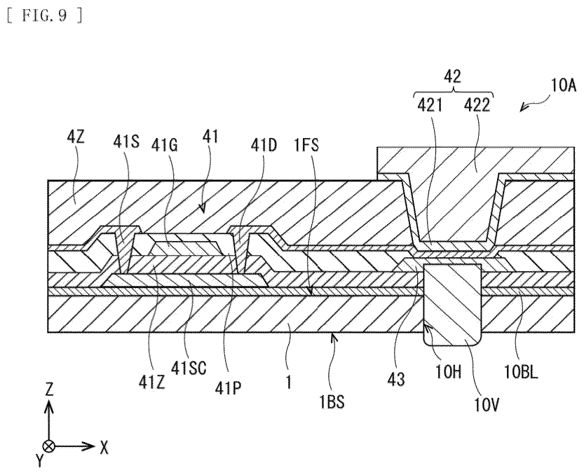

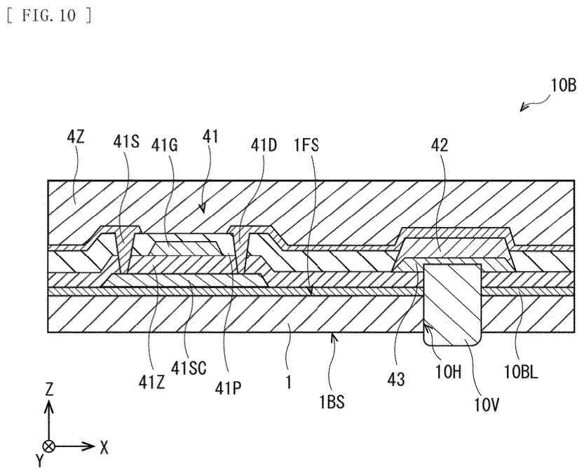

FIG. 9 is a cross-sectional diagram illustrating a configuration example of a light source unit 10A according to a first modification example of the first embodiment. The light source unit 10 of the above-described first embodiment exemplifies a case where the driving device 41 is a bottom-gate thin film transistor. In contrast, in the light source unit 10A as this modification example, the driving device 41 is a top-gate thin film transistor. Specifically, the driving device 41 of the light source unit 10A has a structure in which, on the buffer layer 10BL formed on the insulating film substrate 1, the semiconductor layer 41SC, the gate insulating film 41Z, and the gate electrode 41G are sequentially formed. It is to be noted that the gate electrode 41G is covered with the protective film 41P. Further, the source electrode 41S and the drain electrode 41D are provided on the protective film 41P, and a portion of the source electrode 41S and a portion of the drain electrode 41D extend in the Z axis direction to be coupled to the semiconductor layer 41SC. Further, the driving device 41 of the light source unit 10A includes a metal layer 43 in place of the metal layer 40. The metal layer 43 is formed in the same layer as the gate electrode 41G, that is, formed on the gate insulating film 41Z. The metal layer 43 is provided in a region different from the gate electrode 41G in the XY plane. In the light source unit 10A of FIG. 10, in the Z axis direction, the wiring layer 42 is stacked above the metal layer 43 through intermediation of the drain electrode 41D. It is to be noted that, in the light source unit 10A, the wiring layer 42 may be stacked above the metal layer 43 through intermediation of the source electrode 41S. Even in the light source unit 10A, it is possible to use the wiring layer 42 as an etching stopper at the time of forming the through hole 10H.

Even in a light emitting apparatus including such a light source unit 10A, actions and effects similar to those of the light emitting apparatus including the light source unit 10 are expectable.

### Second Modification Example

FIG. 10 is a cross-sectional diagram illustrating a configuration example of a light source unit 10B according to a second modification example of the first embodiment. In the light source unit 10B, the wiring layer 42 is provided between the gate insulating film 41Z and the drain electrode 41D in the Z axis direction. For example, the wiring layer 42 is provided directly on the metal layer 43. Even in the light source unit 10B, it is possible to use the wiring layer 42 as an etching stopper at the time of forming the through hole 10H.

Even in a light emitting apparatus including such a light source unit 10B, actions and effects similar to those of the light emitting apparatus including the light source unit 10 are expectable.

### Third Modification Example

FIG. 11 is a cross-sectional diagram illustrating a configuration example of a light source unit 10C according to a third modification example of the first embodiment. In the light source unit 10C, the wiring layer 42 is provided on the source electrode 41S and the drain electrode 41D. The wiring layer 42 is, for example, electrically continuous with the metal layer 43 via the drain electrode 41D. Even in the light source unit 10C, it is possible to use the wiring layer 42 as an etching stopper at the time of forming the through hole 10H. It is to be noted that the wiring layer 42 may be electrically continuous with the metal layer 43 via the source electrode 41S.

Even in a light emitting apparatus including such a light source unit 10C, actions and effects similar to those of the light emitting apparatus including the light source unit 10 are expectable.

### Fourth Modification Example

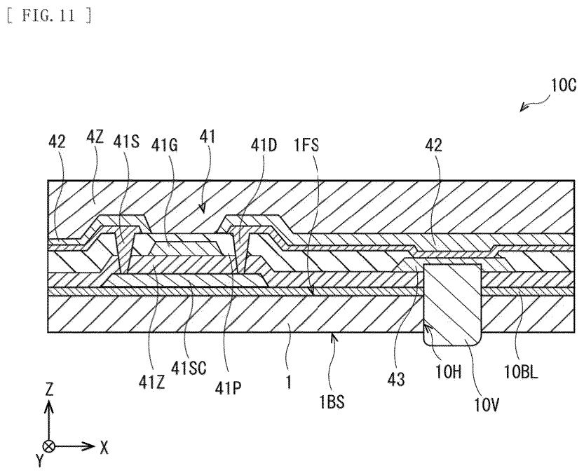

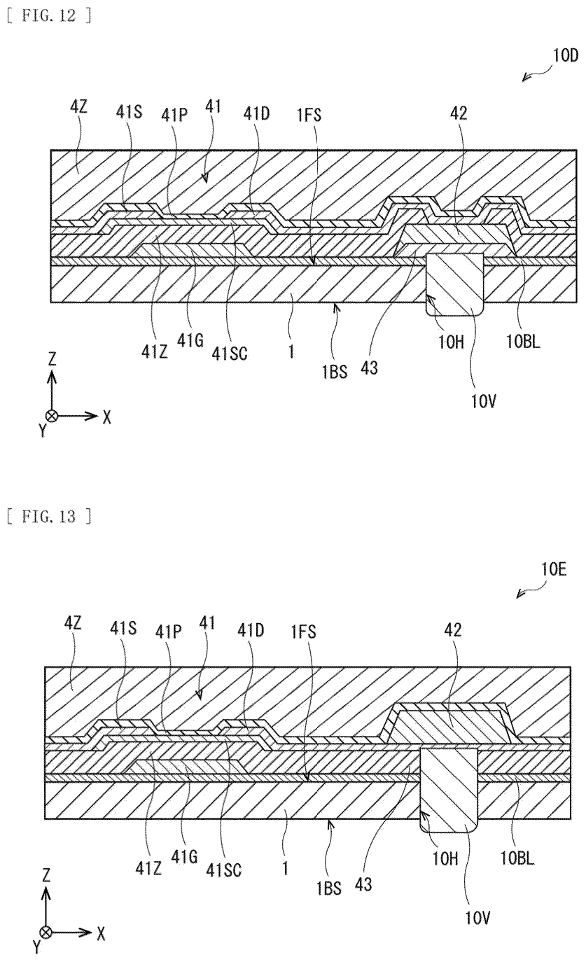

FIG. 12 is a cross-sectional diagram illustrating a configuration example of a light source unit 10D according to a fourth modification example of the first embodiment. In the light source unit 10D, the wiring layer 42 is provided between the gate insulating film 41Z and the drain electrode 41D in the Z axis direction. Further, the driving device 41 of the light source unit 10D includes the metal layer 43 in place of the metal layer 40. The metal layer 43 is formed in the same layer as the gate electrode 41G, that is, formed on the buffer layer 10BL. The metal layer 43 is provided in a region different from the gate electrode 41G in the XY plane. The configuration of the light source unit 10D is substantially the same as the configuration of the light source unit 10 except for those points. For example, the wiring layer 42 is provided directly on the metal layer 43. Even in the light source unit 10D, it is possible to use the wiring layer 42 as an etching stopper at the time of forming the through hole 10H.

Even in a light emitting apparatus including such a light source unit 10D, actions and effects similar to those of the light emitting apparatus including the light source unit 10 are expectable.

### Fifth Modification Example

FIG. 13 is a cross-sectional diagram illustrating a configuration example of a light source unit 10E according to a fifth modification example of the first embodiment. In the light source unit 10E, the wiring layer 42 is provided on the drain electrode 41D. Further, the wiring layer 42 is covered with the insulating layer 4Z together with the source electrode 41S and the drain electrode 41D. The configuration of the light source unit 10E is substantially the same as the configuration of the light source unit 10 except for those points. Even in the light source unit 10E, it is possible to use the wiring layer 42 as an etching stopper at the time of forming the through hole 10H.

Even in a light emitting apparatus including such a light source unit 10E, actions and effects similar to those of the light emitting apparatus including the light source unit 10 are expectable.

### 2. Second Embodiment

### 2.1 Configuration

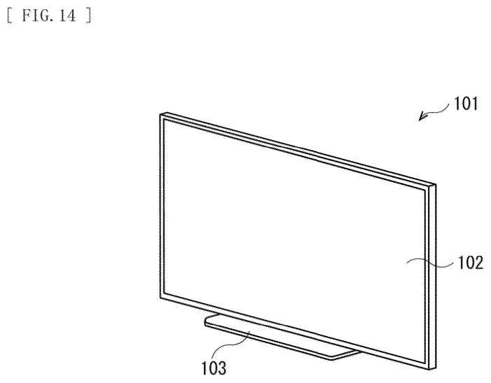

FIG. 14 illustrates an external appearance of a display apparatus 101 according to a second embodiment of the present technique. The display apparatus 101 includes the display panel 210, and is used as, for example, a thin-screen television apparatus. The display apparatus 101 has a configuration in which a flat plate-shaped main body portion 102 for displaying an image is supported by a stand 103. It is to be noted that the display apparatus 101 is used as a stationary type while being placed on a horizontal surface such as a floor, a shelf, or a table under a state in which the stand 103 is mounted to the main body portion 102, but it is possible to use the display apparatus 101 as a wall-mounted type under a state in which the stand 103 is removed from the main body portion 102.

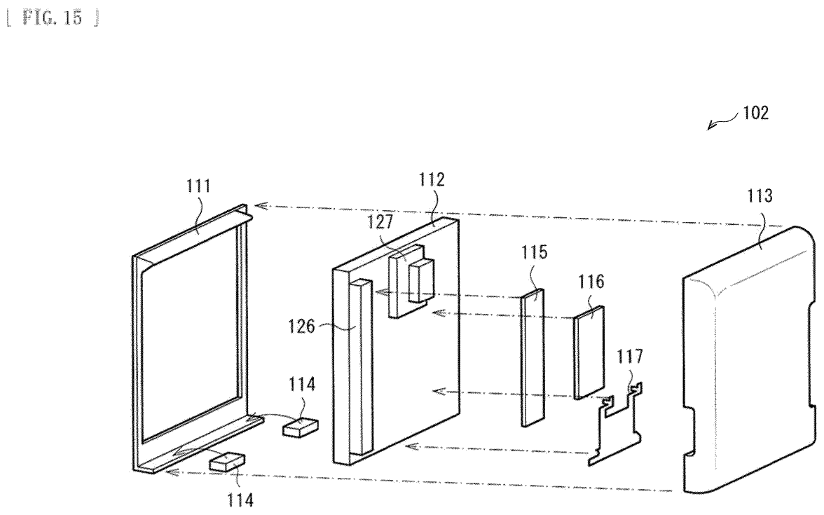

FIG. 15 illustrates the main body portion 102 illustrated in FIG. 14 in a disassembled manner. The main body portion 102 includes, for example, from a front side (viewer side), a front exterior member (bezel) 111, a panel module 112, and a rear exterior member (rear cover) 113 in the stated order. The front exterior member 111 is a frame-like member covering a front peripheral edge portion of the panel module 112, and a pair of speakers 114 is disposed on the lower side. The panel module 112 is fixed to the front exterior member 111, and, on its back surface, a power supply substrate 115 and a signal substrate 116 are mounted and a mounting bracket 117 is fixed. The mounting bracket 117 is provided for mounting a wall bracket, mounting a substrate or the like, and mounting the stand 103. The rear exterior member 113 covers the back surface and the side surface of the panel module 112.

### 2.2 Actions and Effects

The display apparatus 101 includes the display panel 210 suitable for reducing the thickness and the weight. Thus, reduction in thickness and weight of the display apparatus 101 is expectable. Moreover, in the display panel 210, the plurality of light sources 2 is disposed at a higher density. This makes it possible for the display apparatus 101 to exert excellent display performance.

### 3. Other Modification Examples

The present disclosure has been described above by means of embodiments and modification examples, but the present disclosure is not limited to the above-described embodiments and the like, and various modifications are allowed. For example, materials, types, layout positions, shapes, and the like of the components of the display panel described in the above-described embodiments are not limited to those described above.

### Other First Modification Example

For example, the above-described first embodiment exemplifies an LED display including a plurality of LEDs, but the technique of the present disclosure is also applicable to, for example, an organic EL display including organic light emitting devices.

FIG. 16 illustrates a cross-sectional configuration of a display apparatus 500 that is an organic EL display serving as another first modification example of the present disclosure. The display apparatus 500 includes, for example, a support base 510, an image display layer 520, and a protection base 530. The display apparatus 500 is, for example, a top-emission display apparatus that emits light H (HR, HG, and HB) for image display generated in the image display 520 to the outside via the protection base 530. This allows an image to be displayed on a surface (a display surface M1) on a side on which the protection base 530 is disposed.

The image display layer 520 includes a plurality of organic light emitting devices 526 that emits the light H with use of an organic electroluminescence phenomenon. In this case, the image display layer 520 includes, for example, a red organic light emitting device 526R that emits red light HR (for example, having a wavelength in the vicinity of about 620 nm), a green organic light emitting device 526G that emits green light HG (for example, having a wavelength in the vicinity of about 530 nm), and a blue organic light emitting device 526B that emits blue light HB (for example, having a wavelength in the vicinity of about 460 nm).

More specifically, the image display layer 520 includes, for example, a plurality of driving devices 521, an interlayer insulating layer 522, a plurality of driving wirings 523, a planarization insulating layer 524, an in-layer insulating layer 525, the red organic light emitting device 526R, the green organic light emitting device 526G, and the blue organic light emitting device 526B, a protective layer 527, an adhesive layer 528, and a color filter 529. Those series of components of the image display layer 520 are, for example, formed in the stated order on one surface of the support base to be stacked in this order.

### Plurality of Driving Devices

Each of the plurality of driving devices 521 is a device that drives a corresponding one of the red organic light emitting device 526R, the green organic light emitting device 526G, and the blue organic light emitting device 526B, and is disposed in a matrix, for example. Each of the plurality of driving devices 521 is, for example, a thin film transistor (TFT: thin film transistor), and is coupled to the driving wiring 523.

### Interlayer Insulating Layer

The interlayer insulating layer 522 is a layer that electrically isolates the plurality of driving devices 521 from the surroundings and includes, for example, any one type or two or more types of insulating materials such as silicon oxide (SiO₂) or PSG (phospho-silicate glass). For example, the interlayer insulating layer 522 is formed to cover the plurality of driving devices 521 and the support base 510 around the plurality of driving devices 521.

### Plurality of Driving Wirings

Each of the plurality of driving wirings 523 is a wiring functioning as a signal line for driving a corresponding one of the red organic light emitting device 526R, the green organic light emitting device 526G, and the blue organic light emitting device 526B, and includes, for example, any one type or two or more types of conductive materials such as aluminum (Al) or an aluminum copper alloy (AlCu). Each of the plurality of driving wirings 523 is coupled to a corresponding one of the red organic light emitting device 526R, the green organic light emitting device 526G, and the blue organic light emitting device 526B. It is to be noted that, for example, two driving wirings 523 are provided for each driving device 521, and the two driving wirings 523 function as, for example, a gate signal line and a drain signal line.

### Planarization Insulating Layer

The planarization insulating layer 524 is a layer for electrical isolation between each of the driving device 521 and the driving wiring 523 and each of the red organic light emitting device 526R, the green organic light emitting device 526G, and the blue organic light emitting device 526B. It is to be noted that the planarization insulating layer 524 also plays a role as a layer that planarizes a base on which each of the red organic light emitting device 526R, the green organic light emitting device 526G, and the blue organic light emitting device 526B is disposed. The planarization insulating layer 524 includes, for example, any one type or two or more types of insulating materials such as silicon oxide (SiO₂).

### Red Organic Light Emitting Device, Green Organic Light Emitting Device, and Blue Organic Light Emitting Device

The red organic light emitting device 526R, the green organic light emitting device 526G, and the blue organic light emitting device 526B are disposed in a matrix similarly to the driving devices 521. The image display layer 520 includes, assuming the red organic light emitting device 526R, the green organic light emitting device 526G, and the blue organic light emitting device 526B as one set, a plurality of sets of the red organic light emitting device 526R, the green organic light emitting device 526G, and the blue organic light emitting device 526B.

The red organic light emitting device 526R includes, for example, a lower electrode layer 5261, an organic light emitting layer 5262, and an upper electrode layer 5263. For example, the lower electrode layer 5261, the organic light emitting layer 5262, and the upper electrode layer 5263 are stacked on the planarization insulating layer 524 in the stated order.

The lower electrode layer 5261 is an individual electrode disposed in a matrix similarly to the plurality of driving devices 521, and includes, for example, any one type or two or more types of conductive materials such as silver (Ag) or gold (Au).

The organic light emitting layer 5262 is a layer that emits red light HR, and is, for example, a laminate including a plurality of layers. The plurality of layers includes, for example, any one type or two or more types of a hole injection layer, a hole transport layer, an electrode injection layer, a hole transport layer, and the like, in addition to a light emitting layer that generates the red light HR.

The upper electrode layer 5263 is, unlike the lower electrode layer 5261 (individual electrode) disposed in a matrix, a common electrode extending via each of the red organic light emitting device 526R, the green organic light emitting device 526G, and the blue organic light emitting device 526B. The upper electrode 5263 includes, for example, any one type or two or more types of light transmitting conductive materials such as indium tin oxide (ITO: Indium Tin Oxide) in order to introduce the red light HR emitted from the organic light emitting layer 5262 to the protection base 530.

The green organic light emitting device 525G has a configuration similar to that of the red organic light emitting device 526R except for including, for example, the organic light emitting layer 5262 that emits green light HG in place of the organic light emitting layer 5262 that emits the red light HR. The blue organic light emitting device 526B has a configuration similar to that of the red organic light emitting device 526R except for including, for example, the organic light emitting layer 5262 that emits blue light HB in place of the organic light emitting layer 5262 that emits the red light HR.

### In-Layer Insulating Layer

The in-layer insulating layer 526 is a layer for isolating the red organic light emitting device 526R, the green organic light emitting device 526G, and the blue organic light emitting device 526B from each other, and includes, for example, any one type or two or more types of insulating materials such as polyimide.

### Protective Layer

The protective layer 527 is a layer that protects the red organic light emitting device 526R, the green organic light emitting device 526G, the blue organic light emitting device 526B, and the like, and includes, for example, any one type or two or more types of light transmitting dielectric materials such as silicon nitride (SiN).

### Adhesive Layer

The adhesive layer 528 is a layer that causes the protective layer 527 and the color filter 529 to adhere to each other, and includes, for example, any one type or two or more types of adhesives such as a light transmitting thermosetting resin.

### Color Filter

The color filter 529 is a member that transmits the red light HR, the green light HG, and the blue light HB generated in the red organic light emitting device 526R, the green organic light emitting device 526G, and the blue organic light emitting device 526B, respectively. It is to be noted that the color filter 529 also plays a role in preventing the contrast from being reduced due to entry of external light into the image display layer 520.

The color filter 529 includes, for example, a red filter region 529R corresponding to the red organic light emitting device 526R, a green filter region 529G corresponding to the green organic light emitting device 526G, and a blue filter region 529B corresponding to the blue organic light emitting device 526B.

Even in such a display apparatus 500, when the technique of the present disclosure is applied thereto, reduction in thickness and weight is expectable. Moreover, it is possible to dispose the plurality of organic light emitting devices 526 at a high density even in the display apparatus 500. This makes it possible for the display apparatus 500 to exert excellent display performance.

### Other Second Modification Example

Further, the technique of the present disclosure is also applicable to a light emitting apparatus 600 described below.

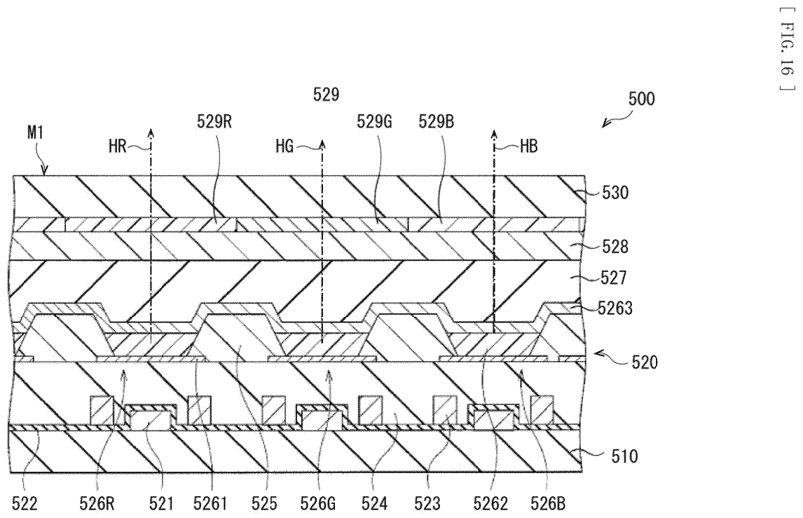

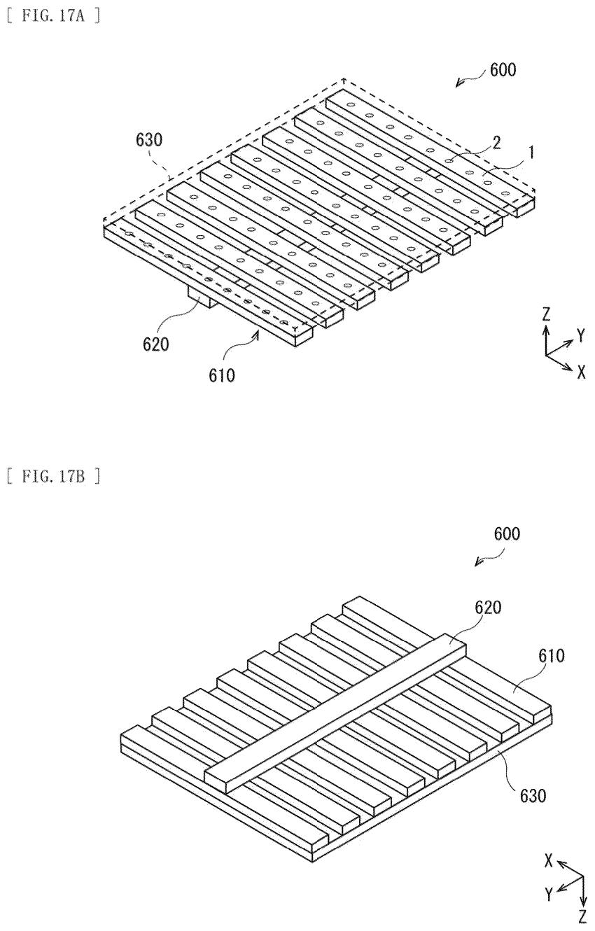

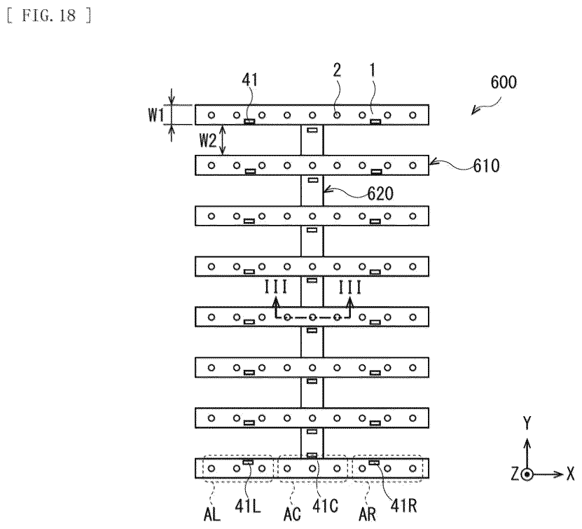

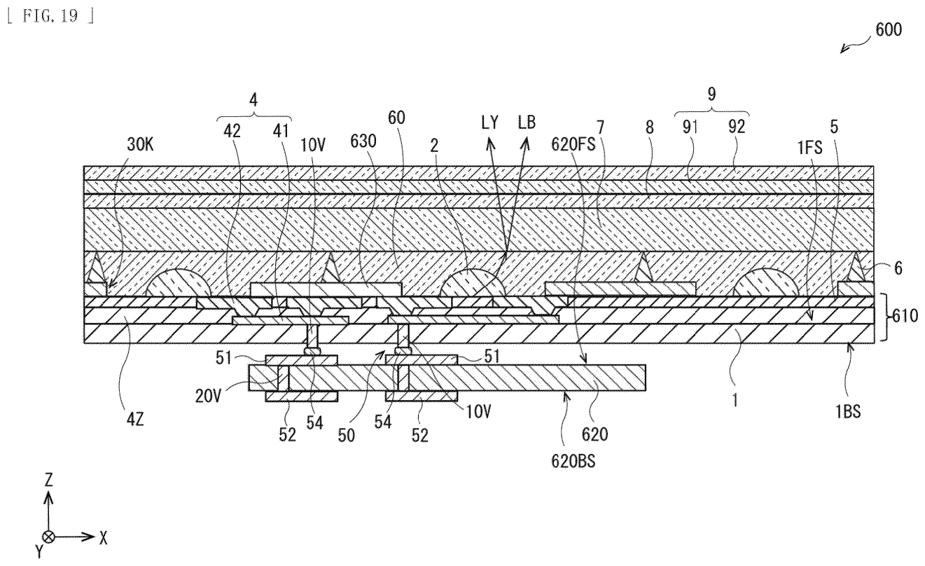

FIG. 17A and FIG. 17B are each a cross-sectional diagram illustrating a configuration example of the light emitting apparatus 600 serving as another second modification example of the present disclosure. FIG. 17A and FIG. 17B illustrate states of the light emitting apparatus 600 as viewed from directions opposite to each other. FIG. 18 is a plan diagram illustrating a plan configuration example of the light emitting apparatus 600 illustrated in FIG. 17A. Moreover, FIG. 19 is a cross-sectional diagram illustrating a cross-sectional configuration example of the light emitting apparatus 600 illustrated in FIG. 17A. It is to be noted that FIG. 19 illustrates a cross section as viewed in the arrow direction taken along the cutting line XIX-XIX of FIG. 18. The light emitting apparatus 600 is suitable as a surface light source, and is used as, for example, a direct-type backlight to be mounted to a liquid crystal display apparatus.

The light emitting apparatus 600 includes, for example, a plurality of light source units 610, a relay substrate 620, and a flexible film 630. The plurality of light source units 610 and the relay substrate 620 have substantially the same configurations as the respective configurations of the light source unit 10 and the circuit board 20 described above in the first embodiment. Each of the plurality of light source units 610 extends in the X axis direction, and is arranged side by side in the Y axis direction. In contrast, the relay substrate 620 extends, for example, in the Y axis direction, and is mechanically joined to each of the plurality of light source units 610. The relay substrate 620 is also electrically coupled to each of the plurality of light source units 610 by a plurality of coupling portions 650. The flexible film 630 is, for example, a reflection sheet, and has, for example, a high reflectance with respect to the light from the light source 2. The flexible film 630 may include titanium oxide or Ag (silver) as a material having a high reflectance. The flexible film 630 is specifically, for example, a white resist layer. Examples of the white resist include inorganic materials such as titanium oxide (TiO₂) fine particles or barium sulfate (BaSO₄) fine particles, and organic materials such as porous acrylic resin fine particles having countless pores for light scattering or polycarbonate resin fine particles. An epoxy-based resin may also be used as the constituent material of the flexible film 630. Moreover, the flexible film 630 may be configured by a resin containing fine particles of inorganic materials, such as titanium oxide (TiO₂) fine particles or barium sulfate (BaSO₄) fine particles.

It is to be noted that, in this modification example, a longitudinal direction of the light source unit 610 is regarded as the X axis direction, a transverse direction of the light source unit 610 is regarded as the Y axis direction, and a thickness direction of the light source unit 610 is regarded as the Z axis direction. The X axis direction, the Y axis direction, and the Z axis direction are orthogonal to each other.

As illustrated in FIG. 17A, each light source unit 610 includes the insulating film substrate 1 and the plurality of light sources 2. As illustrated in FIG. 19, the insulating film substrate 1 includes the front surface 1FS and the back surface 1BS on a side opposite to the front surface 1FS in the thickness direction (Z axis direction). The plurality of light sources 2 is provided on the front surface 1FS (FIG. 19) of the insulating film substrate 1. The plurality of light sources 2 is arrayed at a predetermined interval in, for example, one row along the X axis direction that is the longitudinal direction of the insulating film substrate 1. Further, the flexible film 630 extends along the XY plane, and is provided on the front surface 1FS side of the insulating film substrate 1 to cover all of the plurality of light source units 610. The plurality of light source units 610 is preferred to be fixed to the flexible film 630 by, for example, adhesion. The relay substrate 620 is provided on the back surface 1BS side of the insulating film substrate 1.

The light emitting apparatus 600 includes, as illustrated in FIG. 18 and FIG. 19, the thin film device 4 including the driving device 41. The driving device 41 may be provided on, for example, the insulating film substrate 1 of each light source unit 610, or may be provided on the relay substrate 620. The light emitting apparatus 600 may further include, as illustrated in FIG. 19, a spacer 6, a diffusion sheet 7, a wavelength conversion sheet 8, and an optical sheet group 9. Further, the sealing layer 60 may be provided between the light source unit 610 and the diffusion sheet 7.

### Light Source Unit 610

For example, the plurality of light source units 610 is preferably arranged to be spaced apart from each other along the Y axis direction, as illustrated in FIG. 17A, FIG. 17B, and FIG. 18. In particular, as illustrated in FIG. 18, a width W1 that is a dimension of each light source unit 610 in the Y axis direction is preferred to be narrower than an interval W2 between the light source units 610 adjacent to each other. One reason for this is that it is possible to reduce the constituent material of the insulating film substrate 1 or the like to reduce the weight. It is to be noted that, in the example illustrated in FIG. 17A, FIG. 17B, and FIG. 18, eight light source units 610 are coupled to one relay substrate 620, but the present disclosure is not limited thereto. Seven or less light source units 610 or nine or more light source units 610 may be coupled to one relay substrate 620.

### Wavelength Conversion Sheet 8

The wavelength conversion sheet 8 is disposed to be opposed to the plurality of light sources 2. FIG. 20 is an enlarged cross-sectional diagram illustrating a portion of the wavelength conversion sheet 8 illustrated in FIG. 19 in an enlarged manner. As illustrated in FIG. 20, the wavelength conversion sheet 8 includes, for example, a particulate wavelength conversion material 81. The wavelength conversion material 81 includes, for example, a fluorescent material (fluorescent substance) such as a fluorescent pigment or a fluorescent dye or a quantum dot, and is excited by light from the light source 2 to perform wavelength conversion of the light from the light source 2 into light having a wavelength different from the original wavelength with the principle of fluorescence emission or the like, to thereby emit this light. It is to be noted that, in FIG. 20, for simplification, the wavelength conversion material 81 is drawn to be particulate, but the present disclosure is not limited to the wavelength conversion material 81 being particulate.

The wavelength conversion material 81 included in the wavelength conversion sheet 8 absorbs the blue light emitted from the light source 2, and converts part thereof into red light (for example, a wavelength of 620 nm to 750 nm) or green light (for example, a wavelength of 495 nm to 570 nm). In this case, the light of the light source 2 passes through the wavelength conversion sheet 8, and thus red, green, and blue light beams are combined to generate white light. As another example, the wavelength conversion material 81 included in the wavelength conversion sheet 8 may absorb blue light to covert part thereof into yellow light. In this case, the light of the light source 2 passes through the wavelength conversion sheet 8, and thus yellow and blue light beams are combined to generate white light.

The wavelength conversion material 81 included in the wavelength conversion sheet 8 is preferred to include a quantum dot. The quantum dot is a particle having a major axis of about 1 nm to 100 nm, and has a discrete energy level. The energy state of the quantum dot is dependent on its size, and hence it is possible to freely select an emission wavelength by changing the size. Further, a spectral width of emission light of the quantum dot is narrow. The color gamut is enlarged by combining such light beams having steep peaks. Thus, usage of the quantum dot as the wavelength conversion material allows the color gamut to be easily enlarged. Moreover, the quantum dot has a high responsiveness, which makes it possible to efficiently use the light of the light source 2. In addition, the quantum dot has a high stability. Examples of the quantum dot include a compound of a group 12 element and a group 16 element, a compound of a group 13 element and a group 16 element, and a compound of a group 14 element and a group 16 element, and the quantum dot is, for example, CdSe, CdTe, ZnS, CdS, PbS, PbSe, or CdHgTe. Further, because of a request of a Cd-free quantum dot due to environmental restrictions such as RoHS, the quantum dot includes one using, as a core material, an InP-based material, a perovskite CsPbBr3-based material, Zn (Te, Se), or silver indium sulfide which is one of I-III-VI group ternary materials.

### Diffusion Sheet 7

The diffusion sheet 7 is an optical member disposed between the wavelength conversion sheet 8 and the plurality of light sources 2. The diffusion sheet 7 is provided for obtaining a uniform angle distribution of incident light. As the diffusion sheet 7, one diffusion plate or one diffusion sheet may be used, or two or more diffusion plates or two or more diffusion sheets may be used. Further, the diffusion sheet 7 may be a plate-like optical member having a constant thickness and a constant hardness.

### Spacer 6

A spacer 6 is a member for keeping an optical distance between the light source 2 and the diffusion sheet 7.

### Optical Sheet Group 9

The optical sheet group 9 is an optical member disposed on a light output surface side of the wavelength conversion sheet 8, that is, on a side opposite to the diffusion sheet 7 as viewed from the wavelength conversion sheet 8. The optical sheet group 9 includes, for example, sheets or films for improving the luminance. In the example illustrated in FIG. 19, the optical sheet group 9 includes an optical sheet 91 and an optical sheet 92 sequentially stacked on the wavelength conversion sheet 8. The optical sheet 91 and the optical sheet 92 may be joined and integrated with each other. The optical sheet 91 is, for example, a prism sheet. The optical sheet 92 is, for example, a reflective polarizing film such as a DBEF (Dual Brightness Enhancement Film). It is to be noted that the number of optical sheets included in the optical sheet group 9, the type and the stacking order of the plurality of optical sheets included in the optical sheet group 9, and the like are freely selectable.

Even in such a light emitting apparatus 600, when the technique of the present disclosure is applied thereto, reduction in thickness and weight is expectable. Moreover, even in the light emitting apparatus 600, it is possible to dispose the plurality of light sources 2 at a higher density. This makes it possible for the light emitting apparatus 600 to exert excellent light emitting performance.

Further, in the light emitting apparatus 600, the plurality of light source units 610 in each of which the plurality of light sources 2 is disposed is coupled to one relay substrate 620. This makes it possible to finely adjust the disposing position for each of the plurality of light source units 610, and hence optimization of the disposing position of each light source 2 may be easily made. Further, this is advantageous also for weight reduction of the light emitting apparatus 600. That is, when the plurality of light source units 610 is coupled by one relay substrate 620, for example, as compared with a configuration in which the plurality of light sources is disposed on one board-shaped substrate, it is possible to reduce the usage amount of the material of the insulating film substrate 1 while providing the plurality of light sources 2, which makes it possible to reduce the weight and cost. Thus, according to the light emitting apparatus 600, while the weight and the cost are reduced, it is possible to achieve a highly-precise emission luminance distribution.

In the light emitting apparatus 600 of this embodiment, the plurality of light source units 610 is provided side by side while being spaced apart from each other along the Y axis direction. Thus, as compared with the configuration in which the plurality of light sources 2 is disposed on one board-shaped insulating film substrate, it is possible to reduce the usage amount of the material of the insulating film substrate 1 while providing the plurality of light sources 2, which makes it possible to reduce the weight and cost.

Further, in the light emitting apparatus 600 of this embodiment, when the width W1 of the light source unit 610 in the Y axis direction is narrower than the interval W2 between the plurality of light source units 610 adjacent to each other in the Y axis direction, at the time of disposing a predetermined number of light sources 2 as the entire light emitting apparatus 600, as compared with a case where, for example, the width W1 is equivalent to or larger than the interval W2, it is possible to further reduce the usage amount of the material of the insulating film substrate 1, which makes it possible to further reduce the weight and cost.

Further, in the light emitting apparatus 600 of this embodiment, the plurality of light sources 2 is arranged in one row along the X axis direction in the insulating film substrate 1. Thus, at the time of disposing a predetermined number of light sources 2 as the entire light emitting apparatus 600, as compared with a case where, for example, the light sources 2 is arranged in a plurality of rows, it is possible to further reduce the usage amount of the material of the insulating film substrate 1, which makes it possible to further reduce the weight and cost.

### Other Third Modification Example

The electronic apparatus of the present disclosure can use a stacking film in which a conductive film including copper or the like is formed in advance on an insulating film substrate. However, such a conductive film of the stacking film often has large unevenness on its surface. It is thus desirable to smooth the surface of the conductive film by polishing or the like. This is for enhancing the quality of the thin film transistor in the thin film device.

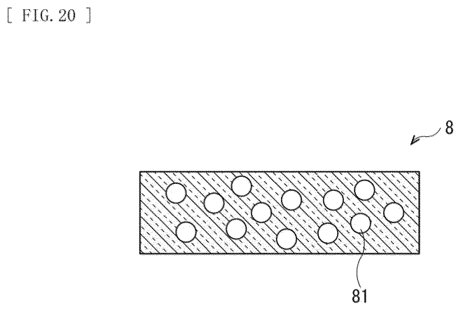

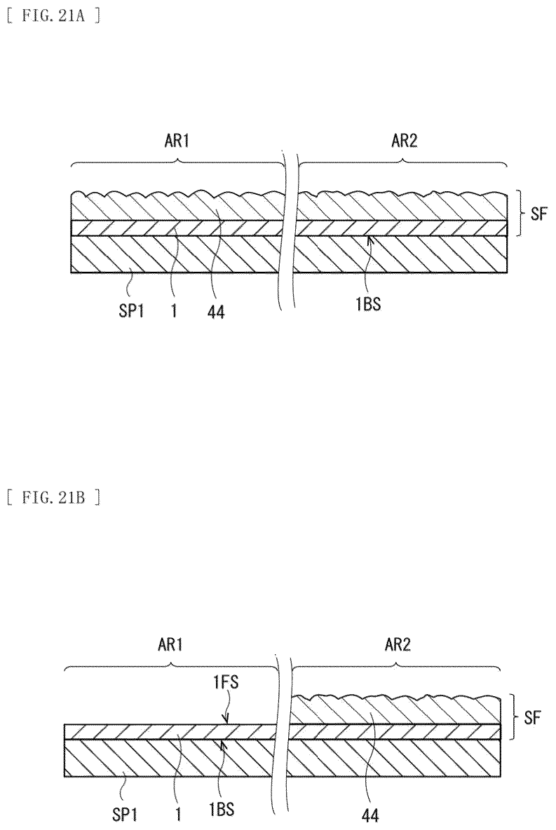

FIG. 21A illustrates a stacking film SF in which a conductive film 44 is formed on the front surface 1FS of the insulating film substrate 1. The back surface 1BS of the stacking film SF is bonded to the support SP1. In a case where the light emitting apparatus is formed with use of such a stacking film SF, it is preferred to perform different types of processing between a region AR1 in which the driving device 41 in the thin film device 4 is to be formed and a region AR2 in which the wiring layer 42 is to be formed.

Specifically, as illustrated in FIG. 21B, the front surface 1FS of the insulating film substrate 1 is exposed by removing the conductive film 44 in the region AR1 in which the driving device 41 is to be formed. Meanwhile, the conductive film 44 of the region AR2 in which the wiring layer 42 is to be formed is left as it is. After that, as illustrated in FIG. 21C, for example, a conductive film Z41G having a uniform thickness of 1 μm or less is formed by, for example, a sputtering method to cover the exposed insulating film substrate 1. It is possible to use the conductive film Z41G as the gate electrode 41G of the driving device 41. Subsequently, as illustrated in FIG. 21D, the thin film device 4 including the driving device 41 is formed in the region AR1, and the thin film device 4 including the wiring layer 42 is formed in the region AR2. After that, as illustrated in FIG. 21E, the resin layer 5 is formed to integrally cover both of the region AR1 and the region AR2. At this time, it is preferred to set the thickness of the resin layer 5 in the region AR1 to be larger than the thickness of the resin layer 5 in the region AR2 to planarize the upper surface of the resin layer 5. This makes it possible to stably bond the upper surface of the resin layer 5 to the support SP2, and at the time of forming a through hole in the insulating film substrate 1, it is possible to enhance its positional accuracy and dimensional accuracy.

### Other Fourth Modification Example

The electronic apparatus of the present disclosure may be manufactured as follows.

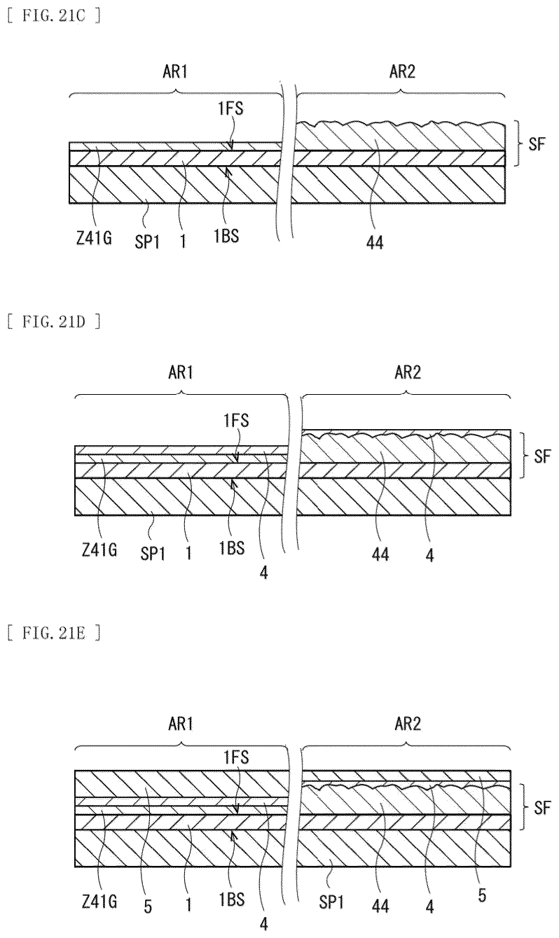

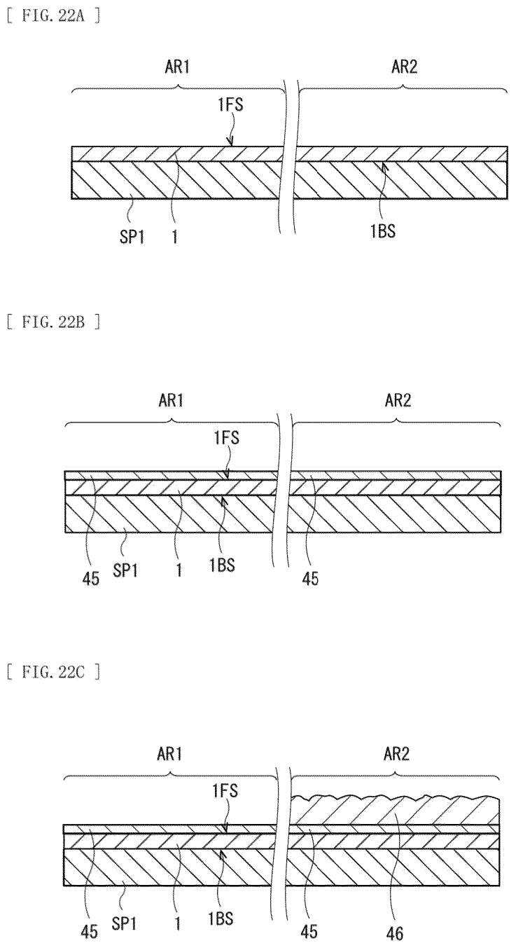

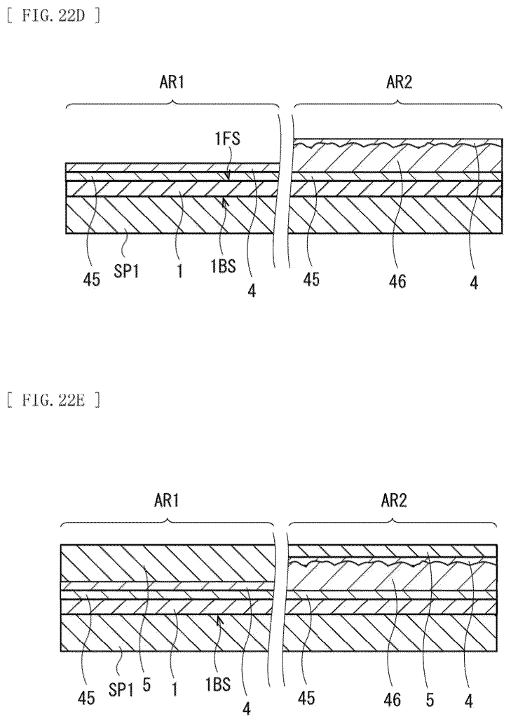

First, as illustrated in FIG. 22A, the insulating film substrate 1 is prepared, and then the back surface 1BS thereof is bonded to the support SP1.

Next, as illustrated in FIG. 22B, for example, the conductive film 45 having a uniform thickness of 1 um or less is formed by, for example, a sputtering method. It is possible to use the conductive film 45 provided in the region AR1 as the gate electrode 41G of the driving device 41. It is possible to configure a portion of the wiring layer 42 by the conductive film 45 provided in the region AR2.

Next, as illustrated in FIG. 22C, a plating film 46 is selectively formed only in the region AR2 by plating treatment using the conductive film 45 provided in the region AR2 as a base layer.

Next, as illustrated in FIG. 22D, the thin film device 4 including the driving device 41 is formed in the region AR1 and the thin film device 4 including the wiring layer 42 is formed in the region AR2.

After that, as illustrated in FIG. 22E, the resin layer 5 is formed to integrally cover both of the region AR1 and the region AR2. At this time, it is preferred to set the thickness of the resin layer 5 in the region AR1 to be larger than the thickness of the resin layer 5 in the region AR2 to planarize the upper surface of the resin layer 5. This makes it possible to stably bond the upper surface of the resin layer 5 to the support SP2, and at the time of forming a through hole in the insulating film substrate 1, it is possible to enhance its positional accuracy and dimensional accuracy.

Further, in the above-described embodiments and the like, a light emitting apparatus including a plurality of light sources each including a light emitting device is exemplified to describe the present disclosure, but the electronic apparatus of the present disclosure is not limited thereto. The electronic apparatus of the present disclosure may include, for example, various electronic devices such as an imaging device or a magnetic sensor. Further, the thin film device is not limited to a thin film transistor, and may be one including only a redistribution layer or the like.

As described above, an electronic apparatus according to one embodiment of the present disclosure includes an insulating film substrate, a thin film device, and a through via. The insulating film substrate includes a first main surface and a second main surface that is on a side opposite to the first main surface. The thin film device includes a metal layer formed on the first main surface of the insulating film substrate. The through via extends from a first part within the metal layer to pass through the insulating film substrate and reach the second main surface. According to the electronic apparatus of one embodiment of the present disclosure, the thin film device is provided on the insulating film substrate, and hence the electronic apparatus has an advantage of reduction in thickness and weight of the overall configuration. Further, formation of the through hole at the time of providing the through via in the insulating film substrate is facilitated.

Further, the effects described herein are only exemplary and are not limited to the descriptions thereof, and other effects may be provided. Further, the present technique may take the following configurations.
(1)

An electronic apparatus including:
an insulating film substrate including a first main surface and a second main surface that is on a side opposite to the first main surface;
a thin film device including a metal layer formed on the first main surface of the insulating film substrate; and
a through via that extends from a first part within the metal layer to pass through the insulating film substrate and reach at least the second main surface.
(2)

The electronic apparatus according to (1), in which the thin film device further includes an additional metal layer selectively stacked in the first part within the metal layer.
(3)

The electronic apparatus according to (1) or (2), further including a buffer layer provided between the first main surface of the insulating film substrate and the thin film device.
(4)

The electronic apparatus according to (3), in which the buffer layer includes an inorganic material.
(5)

The electronic apparatus according to any one of (1) to (3), in which the insulating film substrate includes an organic material.
(6)

The electronic apparatus according to (5), in which the organic material is at least one of PI (polyimide), PET (polyethylene terephthalate), PC (polycarbonate), PEN (polyethylene naphthalate), or COP (cyclo-olefin polymer).
(7)

The electronic apparatus according to any one of (1) to (6), in which the insulating film substrate has flexibility.
(8)

The electronic apparatus according to any one of (1) to (7), in which the thin film device includes at least one of a wiring layer or a thin film transistor.
(9)

The electronic apparatus according to any one of (1) to (7), in which
the thin film device includes a thin film transistor including a gate electrode, a source electrode, and a drain electrode, and
the metal layer is formed in a same layer as the gate electrode, or is formed integrally with the source electrode or the drain electrode.
(10)

The electronic apparatus according to (2), in which the additional metal layer includes a plating layer.
(11)

A light emitting apparatus including:
an insulating film substrate including a first main surface and a second main surface that is on a side opposite to the first main surface;
a thin film device including a metal layer formed on the first main surface of the insulating film substrate;
a light emitting device coupled to the thin film device; and
a through via that extends from a first part within the metal layer to pass through the insulating film substrate and reach the second main surface.
(12)

A display apparatus including:
a light emitting apparatus; and
a display panel including a display region that performs image display with use of light from the light emitting apparatus, in which
the light emitting apparatus includes:
an insulating film substrate including a first main surface and a second main surface that is on a side opposite to the first main surface;
a thin film device including a metal layer formed on the first main surface of the insulating film substrate;
a light emitting device coupled to the thin film device; and
a through via that extends from a first part within the metal layer to pass through the insulating film substrate and reach the second main surface.
(13)

A method of manufacturing the electronic apparatus including:
forming a thin film device including a metal layer on a first main surface of an insulating film substrate, the insulating film substrate including the first main surface and a second main surface that is on a side opposite to the first main surface;
forming a first through hole from the second main surface to reach a first part within the metal layer by selectively removing a partial region of the insulating film substrate; and
forming a through via by filling the first through hole with a conductive material.
(14)

The method of manufacturing the electronic apparatus according to (13), further including forming an additional metal layer on the first part of the metal layer.
(15)

The method of manufacturing the electronic apparatus according to (13) or (14), further including:
forming a buffer layer between the first main surface of the insulating film substrate and the thin film device; and
forming, in the buffer layer, a second through hole communicating with the first through hole.
(16)

The method of manufacturing the electronic apparatus according to (15), further including performing laser irradiation to cause multiphoton absorption in both of the insulating film substrate and the buffer layer to successively form the first through hole and the second through hole.

The present application claims the benefit of Japanese Priority Patent Application JP2022-091164 filed with the Japan Patent Office on Jun. 3, 2022, the entire contents of which are incorporated herein by reference.

It should be understood by those skilled in the art that various modifications, combinations, sub-combinations and alterations may occur depending on design requirements and other factors insofar as they are within the scope of the appended claims or the equivalents thereof.

1. An electronic apparatus comprising:
an insulating film substrate including a first main surface and a second main surface that is on a side opposite to the first main surface;
a thin film device including a metal layer formed on the first main surface of the insulating film substrate; and
a through via that extends from a first part within the metal layer to pass through the insulating film substrate and reach at least the second main surface.

2. The electronic apparatus according to claim 1, wherein the thin film device further includes an additional metal layer selectively stacked in the first part within the metal layer.

3. The electronic apparatus according to claim 1, further comprising a buffer layer provided between the first main surface of the insulating film substrate and the thin film device.

4. The electronic apparatus according to claim 3, wherein the buffer layer includes an inorganic material.

5. The electronic apparatus according to claim 1, wherein the insulating film substrate includes an organic material.

6. The electronic apparatus according to claim 5, wherein the organic material is at least one of PI (polyimide), PET (polyethylene terephthalate), PC (polycarbonate), PEN (polyethylene naphthalate), or COP (cyclo-olefin polymer).

7. The electronic apparatus according to claim 1, wherein the insulating film substrate has flexibility.

8. The electronic apparatus according to claim 1, wherein the thin film device includes at least one of a wiring layer or a thin film transistor.

9. The electronic apparatus according to claim 1, wherein
the thin film device includes a thin film transistor including a gate electrode, a source electrode, and a drain electrode, and
the metal layer is formed in a same layer as the gate electrode, or is formed integrally with the source electrode or the drain electrode.

10. The electronic apparatus according to claim 2, wherein the additional metal layer comprises a plating layer.

11. A light emitting apparatus comprising:
an insulating film substrate including a first main surface and a second main surface that is on a side opposite to the first main surface;
a thin film device including a metal layer formed on the first main surface of the insulating film substrate;
a light emitting device coupled to the thin film device; and
a through via that extends from a first part within the metal layer to pass through the insulating film substrate and reach the second main surface.

12. A display apparatus comprising:
a light emitting apparatus; and
a display panel including a display region that performs image display through use of light from the light emitting apparatus, wherein
the light emitting apparatus includes:
an insulating film substrate including a first main surface and a second main surface that is on a side opposite to the first main surface;
a thin film device including a metal layer formed on the first main surface of the insulating film substrate;
a light emitting device coupled to the thin film device; and
a through via that extends from a first part within the metal layer to pass through the insulating film substrate and reach the second main surface.

13. A method of manufacturing an electronic apparatus comprising:
forming a thin film device including a metal layer on a first main surface of an insulating film substrate, the insulating film substrate including the first main surface and a second main surface that is on a side opposite to the first main surface;
forming a first through hole from the second main surface to reach a first part within the metal layer by selectively removing a partial region of the insulating film substrate; and
forming a through via by filling the first through hole with a conductive material.

14. The method of manufacturing the electronic apparatus according to claim 13, further comprising forming an additional metal layer on the first part of the metal layer.

15. The method of manufacturing the electronic apparatus according to claim 13, further comprising:
forming a buffer layer between the first main surface of the insulating film substrate and the thin film device; and
forming, in the buffer layer, a second through hole communicating with the first through hole.

16. The method of manufacturing the electronic apparatus according to claim 15, further comprising performing laser irradiation to cause multiphoton absorption in both of the insulating film substrate and the buffer layer to successively form the first through hole and the second through hole.
